(19) United States
(12) Patent Application Publication
(10) Pub. No.: US 2025/0234707 A1
(43) Pub. Date: Jul. 17, 2025

(54) DISPLAY DEVICE AND ELECTRONIC DEVICE

(71) Applicant: Semiconductor Energy Laboratory Co., Ltd., Atsugi-shi, Kanagawa-ken (JP)

(72) Inventors: Koji KUSUNOKI, Isehara (JP); Susumu KAWASHIMA, Atsugi (JP); Hideaki SHISHIDO, Atsugi (JP); Tomoaki ATSUMI, Hadano (JP); Motoharu SAITO, Atsugi (JP)

(21) Appl. No.: 18/854,150

(22) PCT Filed: Apr. 10, 2023
(86) PCT No.: PCT/IB2023/053622

§ 371 Date: Oct. 4, 2024

(30) Foreign Application Priority Data
Apr. 22, 2022 (JP) 2022-070483

(51) Int. Cl. H10K 59/121

(52) U.S. Cl. CPC H10K 59/1213

(57) ABSTRACT

A small display device with a narrow bezel is provided. The display device has a stack of a pixel circuit and a driver circuit. The display device has a stack of a first layer to a third layer. The driver circuit is provided in the first layer and the second layer. The pixel circuit is provided in the third layer. The first layer includes a transistor including silicon in a semiconductor layer. The second layer and the third layer each include a transistor including a metal oxide in a semiconductor layer. The transistor included in the second layer has a shorter channel length than the transistor included in the third layer and has a structure suitable for high-speed operation.

### TECHNICAL FIELD

One embodiment of the present invention relates to a display device and an electronic device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof.

Note that in this specification and the like, a semiconductor device refers to every device that can function by utilizing semiconductor characteristics. A transistor, a semiconductor circuit, an arithmetic device, a memory device, and the like are each one embodiment of the semiconductor device. In some cases, an imaging device, an electro-optical device, a power generation device (including a thin film solar cell, an organic thin film solar cell, and the like), and an electronic device each include a semiconductor device.

### BACKGROUND ART

Goggles-type or glasses-type devices have been developed as electronic devices for virtual reality (VR), augmented reality (AR), and the like.

Typical examples of small display devices that can be used for goggles-type or glasses-type devices include a display device including a liquid crystal element and a display device including an organic EL (Electro Luminescence) element, a light-emitting diode (LED), or the like.

A display device including an organic EL element does not need a backlight, which is necessary for a liquid crystal display device; thus, a thin, lightweight, high-contrast, and low-power display device can be achieved. For example, Patent Document 1 discloses an example of a display device including an organic EL element.

Patent Document 2 discloses a technique in which part of a circuit included in a source driver is formed over a glass substrate like a pixel circuit in order to reduce the manufacturing cost and the mounting area of a driver IC provided in a display device.

### REFERENCES

### Patent Documents

[Patent Document 1] Japanese Published Patent Application No. 2002-324673
[Patent Document 2] Japanese Published Patent Application No. 2019-20687

### SUMMARY OF THE INVENTION

### Problems to be Solved by the Invention

Electronic devices used for VR, AR, and the like are a kind of wearable device, which is preferably thin and lightweight in order to have improved portability and wearability. Thus, components included in an electronic device are desired to be small while having required functions.

Increasing pixel density and narrowing a region (bezel) outside a display region are required to downsize a display device.

The display device includes a driver circuit for driving a pixel circuit. Typical examples of the structure of the driver circuit include a structure in which an IC chip is mounted and a structure in which part of the driver circuit is monolithically formed over the same substrate as the pixel circuit. Either of the structures utilizes the bezel region, causing a limitation on narrowing the bezel.

In order to further narrow the bezel, the driver circuit and the display region are preferably provided to overlap with each other. For example, transistors that can be formed using thin films are formed over a silicon substrate where a driver circuit is formed, so that an extremely narrow bezel can be achieved. When part of a driver circuit is formed using transistors that can be formed using thin films, a circuit can be provided on a silicon substrate more freely.

In view of the above, an object of one embodiment of the present invention is to provide a small display device. Another object is to provide a display device with a narrow bezel. Another object is to provide a display device capable of operating at high speed. Another object is to provide a display device with low power consumption. Another object is to provide a high-performance display device. Another object is to provide a novel display device. Another object is to provide an electronic device including the display device. Another object is to provide an electronic device with low power consumption. Another object is to provide a novel electronic device.

Note that the description of these objects does not preclude the existence of other objects. One embodiment of the present invention does not need to achieve all of these objects. Other objects can be derived from the description of the specification, the drawings, the claims, and the like.

### Means for Solving the Problems

One embodiment of the present invention is a display device having a structure in which a driver circuit and a pixel circuit are stacked. A transistor included in part of a component of the driver circuit includes a metal oxide in a semiconductor layer and has a structure suitable for high-speed operation.

A first embodiment of the present invention is a display device including a pixel circuit and a driver circuit including a region overlapping with the pixel circuit. The driver circuit includes a first circuit and a second circuit. The second circuit includes a region overlapping with the first circuit. The pixel circuit includes a region overlapping with the second circuit. The first circuit includes a first transistor including silicon in a channel formation region. The second circuit includes a second transistor including a metal oxide in a semiconductor layer. The pixel circuit includes a third transistor including a metal oxide in a semiconductor layer. The second transistor includes a channel formation region provided along a side surface of an insulating layer.

The first embodiment can be as follows: a first layer, a second layer, and a third layer are included; the second layer is provided between the first layer and the third layer; the pixel circuit is provided in the third layer; the first circuit is provided in the first layer; and the second circuit is provided in the second layer.

A second embodiment of the present invention is a display device including a first layer, a second layer, and a third layer. The second layer is provided between the first layer and the third layer. A pixel circuit is provided in the third layer. A driver circuit of the pixel circuit is provided in each of the first layer and the second layer. A first circuit, which is a component of the driver circuit, is provided in the first layer. A second circuit, which is a component of the driver circuit, is provided in the second layer. The first circuit includes a first transistor including silicon in a channel formation region. The second circuit includes a second transistor including a metal oxide in a semiconductor layer. The pixel circuit includes a third transistor including a metal oxide in a semiconductor layer. The second transistor includes a channel formation region provided along a side surface of an insulating layer included in the second layer.

A third embodiment of the present invention is a display device including a first layer, a second layer, and a third layer. The second layer is provided between the first layer and the third layer. A pixel circuit is provided in each of the second layer and the third layer. A driver circuit of the pixel circuit is provided in each of the first layer and the second layer. A first circuit, which is a component of the driver circuit, is provided in the first layer. A second circuit, which is a component of the driver circuit, and a first component of the pixel circuit are provided in the second layer. A second component of the pixel circuit is provided in the third layer. The first circuit includes a first transistor including silicon in a channel formation region. The second circuit includes a second transistor including a metal oxide in a semiconductor layer. The pixel circuit includes as the first component a fourth transistor including a metal oxide in a semiconductor layer and includes as the second component a third transistor including a metal oxide in a semiconductor layer. The second transistor and the fourth transistor each include a channel formation region provided along a side surface of an insulating layer included in the second layer.

The third embodiment preferably has a structure in which a driving transistor in the pixel circuit is formed with the third transistor, a selection transistor in the pixel circuit is formed with the fourth transistor, the third transistor includes a first conductive layer functioning as a first gate electrode and a second conductive layer functioning as a second gate, the first conductive layer and the second conductive layer are electrically connected to each other, and the second conductive layer is electrically connected to one of a source electrode and a drain electrode of the fourth transistor.

In the first to third embodiments, in a stack in which the first conductive layer, the insulating layer, and the second conductive layer are stacked in this order, an opening can be provided in the insulating layer and the second conductive layer so as to reach the first conductive layer.

The transistor including the channel formation region provided along the side surface of the insulating layer can include a semiconductor layer that includes a metal oxide so as to cover the opening; a second insulating layer that is provided over the second conductive layer and the semiconductor layer including the metal oxide so as to cover a depressed portion caused by the opening; and a third conductive layer that is provided over the second insulating layer so as to fill the depressed portion caused by the opening.

In the first to third embodiments, the first circuit and the second circuit are components of a source driver, and the second circuit can include a pass transistor logic circuit. The second circuit can also include a latch circuit.

In the first to third embodiments, the driver circuit is provided in a region with a rectangular top view, and the driver circuit can drive a plurality of pixel circuits provided over the rectangular region. A plurality of rectangular regions can be arranged in a matrix.

In the first to third embodiments, the pixel circuit preferably includes an organic EL element.

Note that an electronic device including the display device described above, a lens, and a visibility adjustment mechanism is also one embodiment of the present invention.

### Effect of the Invention

According to one embodiment of the present invention, a small display device can be provided. A display device with a narrow bezel can be provided. A display device capable of operating at high speed can be provided. A display device with low power consumption can be provided. A high-performance display device can be provided. A novel display device can be provided. An electronic device including the display device can be provided. An electronic device with low power consumption can be provided. A novel electronic device can be provided.

Note that the description of these effects does not preclude the presence of other effects. Note that one embodiment of the present invention does not need to have all the effects. Note that effects other than these can be derived from the description of the specification, the drawings, the claims, and the like.

### BRIEF DESCRIPTION OF THE DRAWINGS

FIG. 1 is a diagram illustrating a structure of a display device.

FIG. 2A to FIG. 2C are diagrams each illustrating a structure of a display device.

FIG. 3 is a block diagram illustrating a display device.

FIG. 4 is a circuit diagram of a voltage generation circuit and a pass transistor logic circuit.

FIG. 5A to FIG. 5C are each a circuit diagram of a latch circuit.

FIG. 6A to FIG. 6D are each a circuit diagram of a pixel circuit.

FIG. 7A and FIG. 7B are diagrams illustrating a vertical transistor.

FIG. 8A to FIG. 8C are diagrams illustrating a structure example of a display panel.

FIG. 9A and FIG. 9B are diagrams each illustrating a structure example of a display panel.

FIG. 10A to FIG. 10F are diagrams each illustrating a structure example of a pixel.

FIG. 11A and FIG. 11B are diagrams illustrating a structure example of a display panel.

FIG. 12 is a diagram illustrating a structure example of a display panel.

FIG. 13 is a diagram illustrating a structure example of a display panel.

FIG. 14 is a diagram illustrating a structure example of a display panel.

FIG. 15A to FIG. 15F are diagrams each illustrating a structure example of a light-emitting device.

FIG. 16A to FIG. 16C are diagrams each illustrating a structure example of a light-emitting device.

FIG. 17A to FIG. 17F are diagrams illustrating electronic devices.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description in the following embodiments. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

Even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitor elements are separately arranged in a plurality of positions.

One conductor has a plurality of functions of a wiring, an electrode, a terminal, and the like in some cases. In this specification, a plurality of names are used for the same component in some cases. Even in the case where components are illustrated in a circuit diagram as if they were directly connected to each other, the components may actually be connected to each other through one or more conductors; in this specification, even such a structure is included in the category of direct connection.

In drawings and the like illustrating a stacked-layer structure, components other than components included in each layer may be included. In a structure in which two layers are in contact with each other, a component positioned near the boundary is illustrated as a component of one layer for convenience, but may be a component of the other layer.

### Embodiment 1

In this embodiment, a display device of one embodiment of the present invention will be described.

One embodiment of the present invention is a narrow-bezel display device having a structure in which a driver circuit and a pixel circuit are stacked. The driver circuit is provided in each of a first layer and a second layer, and the pixel circuit is provided in a third layer. The second layer is positioned between the first layer and the third layer. Note that part of the pixel circuit may be provided in the second layer.

The first layer includes a transistor including silicon in a semiconductor layer, and the second layer and the third layer each include a transistor including a metal oxide in a semiconductor layer. The transistor included in the second layer has a shorter channel length than the transistor included in the third layer and has a structure suitable for high-speed operation of a circuit.

Such a structure can achieve a narrow bezel to form a small display device. In addition, part of the driver circuit can be provided in the second layer, which can reduce the area occupied by the driver circuit in the first layer. Thus, a circuit other than the driver circuit can be provided in the first layer, so that the display device can have higher performance.

The driver circuit provided in each of the first layer and the second layer is positioned to overlap with the pixel circuit, which can shorten the wiring length. Accordingly, the wiring resistance and the wiring capacitance can be reduced, achieving a display device with small signal delay and low power consumption. In addition, since a plurality of driver circuits are separately positioned and operated in parallel, the display device can be operated at high speed.

In the structure in which a plurality of driver circuits are separately positioned, the amount of data transfer can be reduced by changing the frame frequency, display definition, and the like in each display region, so that high-speed operation and low power consumption can be achieved. For example, display in the vicinity of a gaze can be performed with a high definition and a high-speed frame frequency, and display outside the vicinity of the gaze can be performed with a low definition and a low-speed frame frequency. Such an operation is also referred to as foveated rendering.

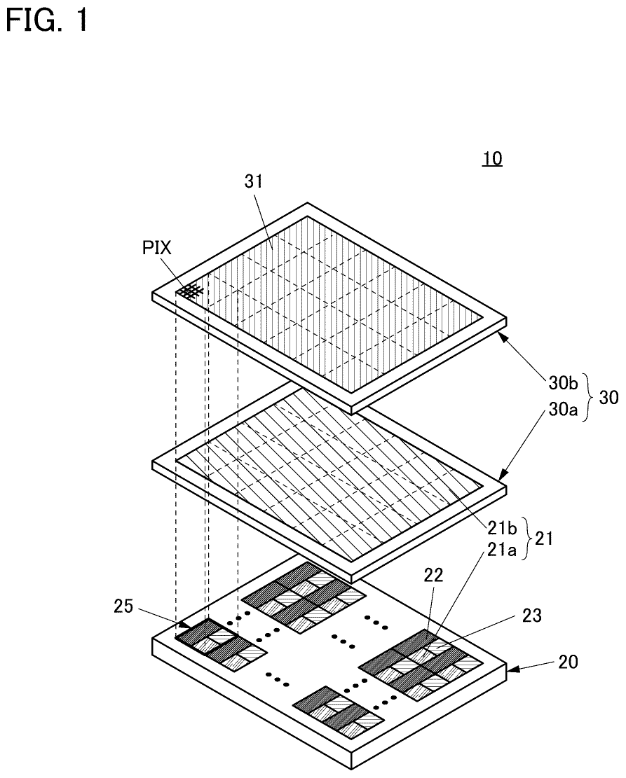

FIG. 1 is a diagram illustrating a display device of one embodiment of the present invention. A display device 10 has a stacked-layer structure including a layer 20, a layer 30a, and a layer 30b, which are illustrated separately in FIG. 1. Note that the layer 30a and the layer 30b are sometimes referred to as a layer 30 without being distinguished from each other. A wiring layer or the like may be provided separately between the layers.

The layer 20 includes components of a circuit for driving a pixel circuit PIX, which is provided in the layer 30b. For example, a gate driver 22, a circuit 21a as a component of a source driver 21, a functional circuit 23, and the like can be provided in the layer 20. The gate driver 22 has a function of selecting the pixel circuit PIX to which image data is to be supplied. The source driver 21 has a function of supplying image data to the pixel circuit PIX. As the functional circuit 23, a memory circuit that temporarily stores image data, correction data, or the like, a timing generation circuit, a power supply circuit, an arithmetic circuit, or the like can be used.

A pair of driver circuits (the gate driver 22 and the source driver 21) can be positioned in a region 25 having a rectangular shape in a top view. A plurality of regions 25 are arranged in a matrix, and the driver circuits in the regions 25 drive a dividing pixel array 31 (a plurality of pixel circuits PIX) over the regions 25, so that the whole display region can be divided into a plurality of regions to be driven.

In the case where the driver circuit is provided in a bezel, there is a limitation on the degree of freedom of arrangement of the driver circuit, which leads to a limited number of regions to be separately driven. Meanwhile, this structure allows the driver circuit to be positioned to overlap with the pixel circuit, so that a larger number of regions can be driven separately.

For example, in the case where the number of regions 25 each provided with a pair of driver circuits is 32 (4×8), the display region can be divided into 32 regions to be driven in parallel, which allows high-speed display operation. The aforementioned foveated rendering is also possible. Note that the number of regions separately driven is not limited thereto, and may be determined as appropriate in accordance with the size, definition, display function, and the like of the display region.

The driver circuits and the functional circuit 23 are required to operate at high speed, and thus are preferably formed using transistors that can operate at high speed. For example, a transistor including silicon in a channel formation region (hereinafter referred to as a Si transistor), which has high mobility, can be used as the transistors. In that case, the layer 20 can include a single crystal silicon substrate, an SOI (Silicon on Insulator) substrate, a glass substrate on which polycrystalline silicon is formed, and the like.

The layer 30a can include a circuit 21b, which is a component of the source driver 21. The layer 30b can include the dividing pixel array 31. The dividing pixel array 31 has a structure in which a plurality of pixel circuits PIX are arranged in a matrix. The display region has a structure in which the dividing pixel arrays 31 are arranged in a matrix. Note that some of the transistors included in the pixel circuit PIX may be provided in the layer 30a.

The circuit included in the layer 30 (the layer 30a and the layer 30b) is preferably formed using a transistor including a thin semiconductor layer in a channel formation region. The thin semiconductor layer can be formed through a film formation step, and thus can be easily formed over a Si transistor with an insulating layer therebetween without a bonding step or the like.

For the semiconductor layer that can be formed with a thin film, polycrystalline silicon, amorphous silicon, a metal oxide, or the like can be used. It is particularly preferable to use a metal oxide that enables a transistor with relatively high mobility to be formed without a crystallization step or the like.

Here, the circuit 21b provided in the layer 30a is a component of the source driver 21 and thus is preferably formed using a transistor suitable for high-speed operation of the circuit. In one embodiment of the present invention, a vertical transistor including a metal oxide in a semiconductor layer (hereinafter referred to as a first OS transistor) is used as the transistor.

Note that the vertical transistor has a structure in which a channel formation region is provided in a semiconductor layer formed along a side surface of an insulating layer included in a layer, and the channel length is determined by the thickness of the insulating layer. The vertical transistor is advantageous in that the channel length can be reduced without largely depending on the lithography accuracy. A transistor with a short channel length can have a high on-state current. Thus, the vertical transistor can be regarded as a transistor suitable for high-speed operation of the circuit.

As a display element included in the pixel circuit PIX, a light-emitting element that does not need a light source is preferably used. As the light-emitting element, an organic EL element or a micro LED (Light Emitting Diode) can be used.

A plurality of transistors having different characteristics are preferably used in the pixel circuit PIX including the light-emitting element. Thus, transistors formed by a lithography process to have different channel lengths are used in the pixel circuit PIX provided in the layer 30b.

In one embodiment of the present invention, a transistor including a metal oxide in a channel formation region and having a structure different from that of the first OS transistor (hereinafter referred to as a second OS transistor) is used as the transistor. The second OS transistor can be any of a planar transistor, a staggered transistor, an inverted staggered transistor, a trench-type transistor, a fin-type transistor, and the like. In addition, the transistor structure may be either a top-gate structure or a bottom-gate structure. Note that the first OS transistor provided in the layer 30a may be used as some of the transistors included in the pixel circuit PIX.

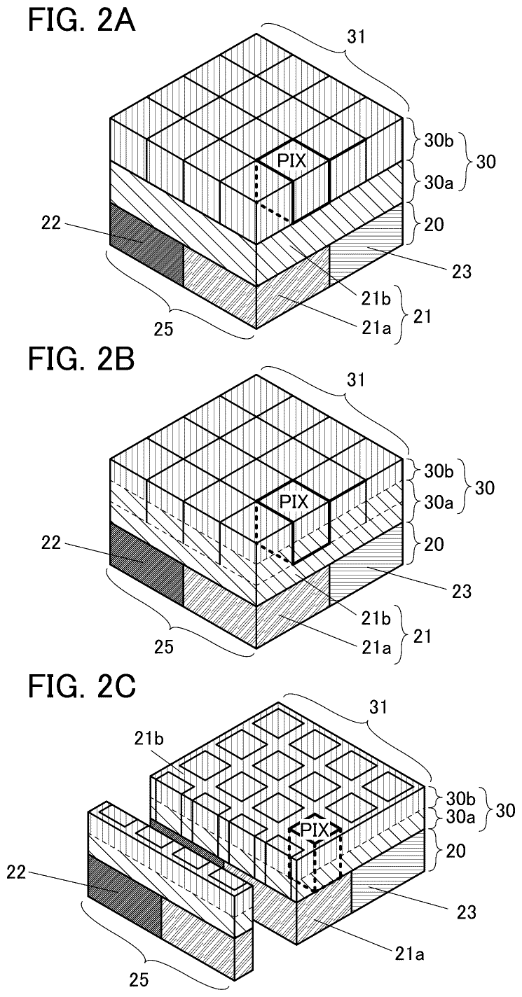

FIG. 2A to FIG. 2C are diagrams illustrating structure examples of the arrangement of a pair of driver circuits (the source driver 21 and the gate driver 22) and the functional circuit 23 provided in the region 25 illustrated in FIG. 1 and the dividing pixel array 31 provided thereover. The pair of driver circuits can drive the dividing pixel array 31 provided over the region 25.

FIG. 2A illustrates an example in which the circuit 21b and the dividing pixel array 31 (the pixel circuits PIX) are provided over the pair of driver circuits and the functional circuit 23. The circuit 21b includes the first OS transistor provided in the layer 30a, and the pixel circuit PIX includes the second OS transistor provided in the layer 30b. Here, the circuit 21b includes a region overlapping with one or more of the circuit 21a, the gate driver 22, and the functional circuit 23. The circuit 21b includes a region overlapping with the pixel circuit PIX. This structure is effective in narrowing the bezel.

FIG. 2B is a modification example of FIG. 2A. The circuit 21b includes the first OS transistor provided in the layer 30a, and the pixel circuit PIX includes the first OS transistor provided in the layer 30a and the second OS transistor provided in the layer 30b. Here, the circuit 21b includes a region overlapping with any one of the circuit 21a, the gate driver 22, and the functional circuit 23. The circuit 21b includes a region overlapping with the pixel circuit PIX.

With this structure, a higher performance pixel as well as a narrower bezel is easily achieved. The structure allows components of the pixel circuit PIX to be formed to overlap with each other, thereby increasing the number of transistors in a unit area of the pixel circuit PIX. Thus, a correction circuit or the like is easily added to the pixel circuit PIX.

FIG. 2C illustrates an example in which the circuit 21b and the dividing pixel array 31 (the pixel circuits PIX) are provided over the pair of driver circuits and the functional circuit 23. Note that part of FIG. 2C is divided to be illustrated clearly.

Each of the circuit 21b and the pixel circuit PIX includes the first OS transistor provided in the layer 30a and the second OS transistor provided in the layer 30b. Here, the circuit 21b includes a region overlapping with one or more of the circuit 21a, the gate driver 22, and the functional circuit 23 and does not include a region overlapping with the pixel circuit PIX. That is, the circuit 21b is formed in a region between pixels.

The above structure, in which the circuit 21b includes the first OS transistor and the second OS transistor, can have an increased degree of freedom of the structure of the circuit 21b in addition to the advantage of FIG. 2B.

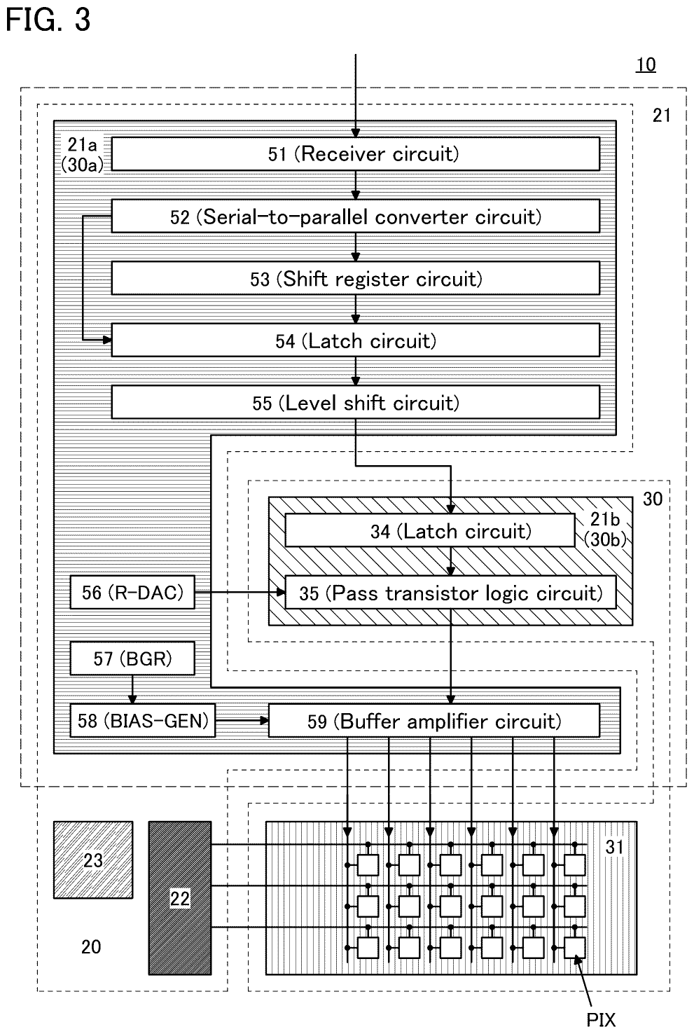

FIG. 3 illustrates a block diagram of the display device 10. The display device 10 includes the source driver 21 (the circuits 21a and 21b), the gate driver 22, the functional circuit 23, the dividing pixel array 31, and the like.

The circuit 21a as a component of the source driver 21 can include a receiver circuit 51, a serial-to-parallel converter circuit 52, a shift register circuit 53, a latch circuit 54, a level shift circuit 55, a voltage generation circuit 56 (R-DAC), a band gap reference circuit 57 (BGR), a bias generation circuit 58 (BIAS-GEN), a buffer amplifier circuit 59, and the like.

The circuit 21b as a component of the source driver 21 can include a latch circuit 34, a pass transistor logic circuit 35, and the like. Note that the latch circuit 34 may be a component of the circuit 21a.

In the circuit 21a, first, serial video data (digital data) is input to the receiver circuit 51 and converted into parallel video data by the serial-to-parallel converter circuit 52. The parallel video data is distributed to a plurality of latch circuits 54 by the shift register circuit 53 and retained therein. Each video data retained in the plurality of latch circuits is boosted by the level shift circuit 55 and output to the circuit 21b.

The boosted parallel video data is input to the pass transistor logic circuit 35 through the plurality of latch circuits 34 included in the circuit 21b. In the pass transistor logic circuit 35, the parallel video data (digital data) is converted into analog data and output to the buffer amplifier circuit 59. The analog data is amplified by the buffer amplifier circuit 59 and output as analog video data to the pixel circuit PIX included in the dividing pixel array 31.

Here, the pass transistor logic circuit 35 is a circuit having a function of converting input digital data into analog data. The pass transistor logic circuit 35 needs a large number of transistors in accordance with the number of gray levels of video data and thus occupies a relatively large area. In addition, the pass transistor logic circuit 35 preferably includes transistors with high withstand voltage in order to have increased output current.

Hence, unlike other circuits that handle digital data, the pass transistor logic circuit 35 is not always appropriate to be formed in the layer 20 using Si transistors. The pass transistor logic circuit 35 can be configured not with a CMOS circuit but with a single-polarity circuit. Thus, in one embodiment of the present invention, the pass transistor logic circuit 35 is formed in the layer 30 using the first OS transistor as a component of the circuit 21b.

Since a transistor including a metal oxide has a lower off-state current than a transistor including silicon, a change in data value due to the influence of a leakage current or the like of the transistor hardly occurs at the time of transmitting analog data or in the case of temporarily retaining the analog data. The transistor including a metal oxide can have higher withstand voltage than the transistor including silicon. The structure of the first OS transistor, which has a short channel length and easily increases the on-state current, is suitable for high-speed operation of a circuit. Thus, when the first OS transistor is used for the pass transistor logic circuit 35, processing and transmission of an analog signal with a relatively high voltage can be performed at high speed with high reliability.

When the pass transistor logic circuit 35 is provided in the layer 30, the area where the functional circuit 23 and the like are provided can be increased in the layer 20. This contributes to higher performance of the display device.

The latch circuit 34 is also preferably formed using the first OS transistor in the layer 30 as a component of the circuit 21b. The first OS transistor has a structure in which a semiconductor layer, an insulating layer, and a conductive layer are formed to overlap with each other along a bottom surface and a side surface of a trench. When the connection mode of the conductive layer is changed, this structure can also be used for a trench-type MOS capacitor that occupies a small area. When the semiconductor layer is omitted, a trench-type MIM capacitor that occupies a small area can be formed. As a result, the area occupied by the latch circuit 34 including a transistor and a capacitor can be reduced. Note that the latch circuit 34 may be provided in the layer 20 as a component of the circuit 21a.

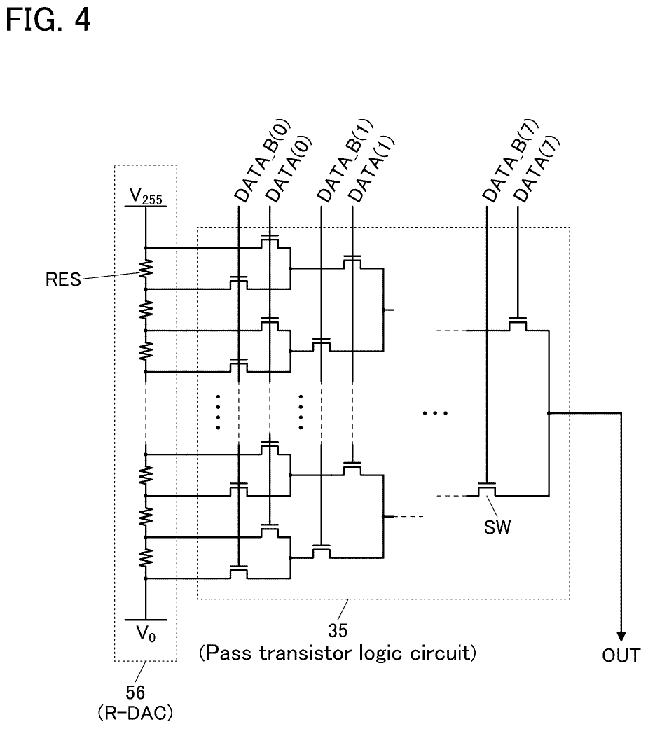

FIG. 4 illustrates a structure example of the pass transistor logic circuit 35. FIG. 4 also illustrates a structure example of the voltage generation circuit 56 (R-DAC) connected to the pass transistor logic circuit 35.

The pass transistor logic circuit 35 is a circuit having a function of converting input digital data into analog data. The voltage generation circuit 56 is a circuit having a function of generating a voltage of analog data output from the pass transistor logic circuit 35. It can be said that the pass transistor logic circuit 35 and the voltage generation circuit 56 form a D/A (digital/analog) converter circuit.

The pass transistor logic circuit 35 illustrated in FIG. 4 is a circuit that outputs analog data corresponding to 8-bit digital data to an output terminal (OUT). Note that the number of bits of input digital data is not limited thereto.

First, the voltage generation circuit 56 is described. FIG. 4 illustrates a circuit example of the voltage generation circuit 56 with a resistive partial pressure system (a resistor string system). The voltage generation circuit 56 is a circuit for generating a plurality of voltages (here, 256 voltages) and has a structure in which a plurality of resistors RES are connected in series.

In the voltage generation circuit 56 illustrated in FIG. 4, a potential V₂₅₅ is supplied to one end of the string of the resistors RES connected in series, and a potential V₀ is supplied to the other end. The voltage V₂₅₅-V₀ is divided into 256 by the plurality of resistors RES and output to the pass transistor logic circuit 35 as an output voltage. Here, the potential V₂₅₅ corresponds to an output potential corresponding to a gray level value of 255, and the potential V₀ corresponds to an output potential corresponding to a gray level value of 0.

Although the structure shown here uses the two potentials of V₂₅₅ and V₀ as references (reference potentials), one or more reference potentials between the potential V₂₅₅ and the potential V₀ may also be used. A larger number of reference potentials enables the voltage generation circuit 56 to output a potential more stably.

Note that the structure of the voltage generation circuit 56 is not limited thereto, and a variety of structures can be used as long as a plurality of potentials can be generated.

Although FIG. 4 illustrates the structure in which one voltage generation circuit 56 is connected to one pass transistor logic circuit 35, one voltage generation circuit 56 may be connected to a plurality of pass transistor logic circuits 35 to supply potentials.

Next, the pass transistor logic circuit 35 is described. The pass transistor logic circuit 35 includes a plurality of switches SW whose conduction states are controlled by DATA(0) to DATA(7) that are input data and DATA_B(0) to DATA_B(7) that are inverted data thereof. Here, for example, DATA(0) is the first-bit data of 8-bit data, and DATA_B(7) is the data obtained by inverting the eighth-bit data.

When the conduction state of the switch SW included in the pass transistor logic circuit 35 is controlled, the voltage of data converted from digital to analog and output from the output terminal (OUT) becomes a voltage corresponding to the gray level voltage supplied to the dividing pixel array 31.

Here, the first OS transistor is used as the plurality of switches SW. Digital data amplified by the level shift circuit 55 is input to the pass transistor logic circuit 35 so that the output current increases. Hence, the pass transistor logic circuit 35 preferably includes transistors with high withstand voltage.

A transistor including a metal oxide in a channel formation region has a feature of having higher withstand voltage than a transistor including silicon, and thus is suitable for a circuit with a high driving voltage. The use of a transistor with a short channel length and a high on-state current like the first OS transistor can increase the operation frequency and output performance of the pass transistor logic circuit 35.

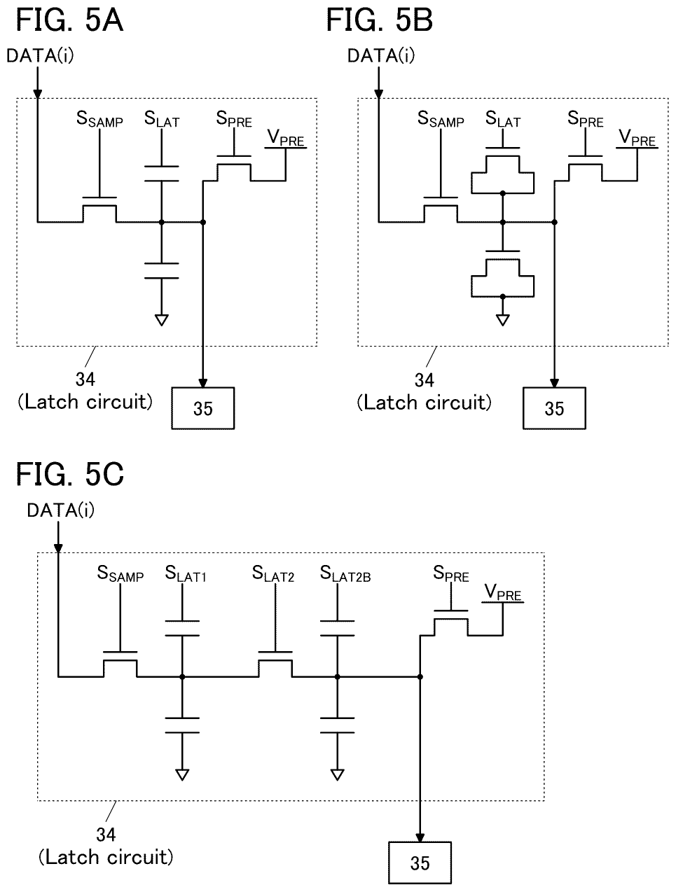

FIG. 5A illustrates a circuit diagram that can be applied to the latch circuit 34. The latch circuit 34 illustrated in FIG. 5A is a sample-and-hold circuit that can retain 1-bit digital data.

The latch circuit 34 includes two transistors and two capacitor elements. The latch circuit 34 has a function of sampling data DATA(i) (i is a bit number) in accordance with a sampling signal S_{SAMP} and a latch signal SLAT and retaining data output to the pass transistor logic circuit 35. In the latch circuit 34, the output potential can precharged to a voltage VPRE in accordance with a precharge signal S_{PRE}.

FIG. 5B illustrates an example in which the two capacitor elements are formed using transistors. Each of the capacitor elements has a structure in which a source and a drain of a transistor are connected to each other. This allows two transistors and two capacitor elements to be formed in the same process. Note that the use of the first OS transistor as a capacitor element is advantageous in that the capacitance can be easily increased.

FIG. 5C illustrates a structure example of the latch circuit 34 including two retention nodes. With such a structure, while output data is retained at one of the two retention nodes that is closer to the output side, data of a subsequent frame can be written to the node closer to the input side. Specifically, data retained at the node closer to the input side is sampled in accordance with a latch signal S_{LAT2} and a latch signal S_{LAT2B}, and the data is retained at the node closer to the output side. While the data is retained, the data DATA(i) of a subsequent frame is sampled in accordance with the sampling signal S_{SAMP} and a latch signal S_{LAT1}, and retained at the node closer to the input side. Note that each of the capacitor elements illustrated in FIG. 5C may be formed using transistors as in FIG. 5B.

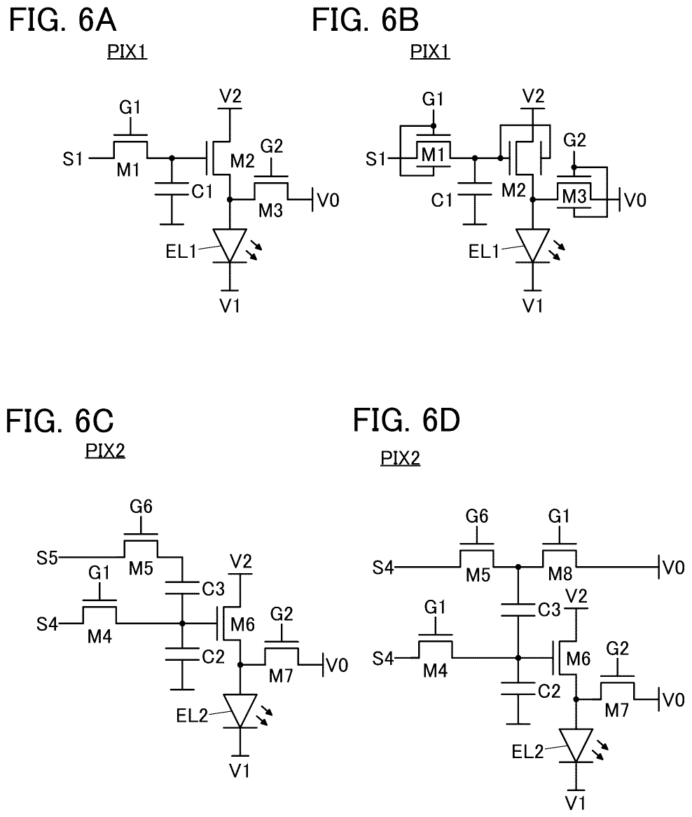

FIG. 6A to FIG. 6C are diagrams illustrating examples of a circuit that can be applied to the pixel circuit PIX included in the dividing pixel array 31.

A circuit PIX1 illustrated in FIG. 6A includes a light-emitting device EL1, a transistor M1, a transistor M2, a transistor M3, and a capacitor element C1. Here, an example in which a light-emitting diode is used as the light-emitting device EL1 is shown. An organic EL element that emits visible light is preferably used as the light-emitting device EL1.

A gate of the transistor M1 is electrically connected to a wiring G1, one of a source and a drain of the transistor M1 is electrically connected to a wiring Si, and the other of the source and the drain of the transistor M1 is electrically connected to one electrode of the capacitor element C1 and a gate of the transistor M2. One of a source and a drain of the transistor M2 is electrically connected to a wiring V2, and the other is electrically connected to an anode of the light-emitting device EL1 and one of a source and a drain of the transistor M3. A gate of the transistor M3 is electrically connected to a wiring G2, and the other of the source and the drain of the transistor M3 is electrically connected to a wiring V0. A cathode of the light-emitting device EL1 is electrically connected to a wiring V1.

A constant potential is supplied to each of the wiring V1 and the wiring V2. Light emission can be performed when the anode side of the light-emitting device EL1 is set to a high potential and the cathode side is set to a low potential. The transistor M1 is controlled by a signal supplied to the wiring G1 and functions as a selection transistor for controlling a selection state of the circuit PIX1. The transistor M2 functions as a driving transistor that controls a current flowing through the light-emitting device EL1 in accordance with a potential supplied to the gate.

When the transistor M1 is in a conduction state, a potential supplied to the wiring Si is supplied to the gate of the transistor M2, and the emission luminance of the light-emitting device EL1 can be controlled in accordance with the potential. The transistor M3 is controlled by a signal supplied to the wiring G2. Accordingly, the potential between the transistor M3 and the light-emitting device EL1 can be reset to a constant potential supplied from the wiring V0; thus, a potential can be written to the gate of the transistor M2 while the source potential of the transistor M2 is stabilized.

Note that as illustrated in FIG. 6B, each of the transistors included in the circuit PIX1 can be provided with two gates. In this specification, one of the two gates is referred to as a first gate or a front gate, and the other of the two gates is referred to as a second gate or a back gate.

FIG. 6B illustrates a structure in which the front gate and the back gate are connected to each other and supplied with the same signal. With this structure, the on-state current can be increased. Note that it is also possible to use a structure in which the two gates are not connected to each other and a constant potential is supplied to the back gate. Such a structure allows control of the threshold voltage of the transistor.

Note that the structure in which the transistor is provided with the back gate can also be applied to a circuit PIX2 described below. The circuit PIX1 and the circuit PIX2 may include both a transistor without a back gate and a transistor with a back gate.

FIG. 6C illustrates an example of the circuit PIX2 which is different from the circuit PIX1. The circuit PIX2 has a function of boosting a voltage. The circuit PIX2 includes a light-emitting device EL2, a transistor M4, a transistor M5, a transistor M6, a transistor M7, a capacitor element C2, and a capacitor element C3.

A gate of the transistor M4 is electrically connected to the wiring G1, one of a source and a drain of the transistor M4 is electrically connected to a wiring S4, and the other of the source and the drain of the transistor M4 is electrically connected to one electrode of the capacitor element C2, one electrode of the capacitor element C3, and a gate of the transistor M6. A gate of the transistor M5 is electrically connected to a wiring G6, one of a source and a drain of the transistor M5 is electrically connected to a wiring S5, and the other of the source and the drain of the transistor M5 is electrically connected to the other electrode of the capacitor element C3.

One of a source and a drain of the transistor M6 is electrically connected to the wiring V2, and the other is electrically connected to an anode of the light-emitting device EL2 and one of a source and a drain of the transistor M7. A gate of the transistor M7 is electrically connected to the wiring G2, and the other of the source and the drain of the transistor M7 is electrically connected to the wiring V0. A cathode of the light-emitting device EL2 is electrically connected to the wiring V1.

The transistor M4 is controlled by a signal supplied to the wiring G1, and the transistor M5 is controlled by a signal supplied to the wiring G6. The transistor M6 functions as a driving transistor that controls the current flowing through the light-emitting device EL2 in accordance with a potential supplied to the gate.

The emission luminance of the light-emitting device EL2 can be controlled in accordance with the potential supplied to the gate of the transistor M6. The transistor M7 is controlled by a signal supplied to the wiring G2. The potential between the transistor M6 and the light-emitting device EL2 can be reset to a constant potential supplied from the wiring V0, and a potential can be written to the gate of the transistor M6 while the source potential of the transistor M6 is stabilized. In addition, when the potential supplied from the wiring V0 is set to the same potential as the potential of the wiring V1 or a potential lower than that of the wiring V1, light emission of the light-emitting device EL2 can be inhibited.

The voltage boosting function of the circuit PIX2 is described below.

First, a potential “D1” of the wiring S4 is supplied to the gate of the transistor M6 through the transistor M4, and at the timing overlapping with this, a reference potential “V_{ref}” is supplied to the other electrode of the capacitor element C3 through the transistor M5. At this time, “D1−V_{ref}” is retained in the capacitor element C3. Next, the gate of the transistor M6 is set to be floating, and a potential “D2” of the wiring S5 is supplied to the other electrode of the capacitor element C3 through the transistor M5. Here, the potential “D2” is a potential for addition.

At this time, the potential of the gate of the transistor M6 is D1+(C₃/(C₃+C₂+C_{M6}))×(D2−V_{ref})), where C₃ is the capacitance value of the capacitor element C3, C₂ is the capacitance value of the capacitor element C2, and C_{M6} is the capacitance value of the gate of the transistor M6. Here, assuming that the value of C₃ is sufficiently larger than the value of C₂+C_{M6}, C₃/(C₃+C₂+C_{M6}) approximates 1. Thus, it can be said that the potential of the gate of the transistor M6 approximates “D1+(D2−V_{ref})”. When D1=D2 and V_{ref}=0, “D1+(D2−V_{ref}))”=“2D1”.

In other words, when the circuit is designed appropriately, a potential approximately twice as high as the potential that can be input from the wiring S4 or S5 can be supplied to the gate of the transistor M6.

Owing to such action, a high voltage can be generated in the pixel circuit. Thus, the voltage to be input to the pixel circuit can be low and the power consumption of the driver circuit can be reduced.

The circuit PIX2 may have a structure illustrated in FIG. 6D. The circuit PIX2 illustrated in FIG. 6D differs from the circuit PIX2 illustrated in FIG. 6C in including a transistor M8. A gate of the transistor M8 is electrically connected to the wiring G1, one of a source and a drain of the transistor M8 is electrically connected to the other of the source and the drain of the transistor M5 and the other electrode of the capacitor element C3, and the other of the source and the drain of the transistor M8 is electrically connected to the wiring V0. The one of the source and the drain of the transistor M5 is connected to the wiring S4.

In the circuit PIX2 illustrated in FIG. 6C, the operations of supplying the reference potential and the potential for addition to the other electrode of the capacitor element C3 through the transistor M5 are performed as described above. In this case, the two wirings S4 and S5 are necessary and the reference potential and the potential for addition need to be rewritten alternately in the wiring S5.

In the circuit PIX2 illustrated in FIG. 6D, although the transistor M8 is additionally provided, the wiring S5 can be omitted because a dedicated path for supplying the reference potential is provided. Since the gate of the transistor M8 can be connected to the wiring G1 and the wiring V0 can be used as a wiring for supplying the reference potential, the number of wirings connected to the transistor M8 does not increase. Moreover, alternate rewriting of the reference potential and the potential for addition is not performed in one wiring, which makes it possible to achieve high-speed operation with low power consumption.

Note that in FIG. 6C and FIG. 6D, “D1B”, an inversion potential of “D1”, may be used as the reference potential “V_{ref}”. In that case, a potential approximately three times as high as the potential that can be input from the wiring S4 or S5 can be supplied to the gate of the transistor M6. Note that the inversion potential refers to a potential that is different from the original potential but has the same (or substantially the same) absolute value of the difference from a reference potential as the original potential. The relation V₀=(D1+D1B)/2 is satisfied, where “D1” is the original potential, “D1B” is the inversion potential, and V₀ is the reference potential.

In the display device of this embodiment, the light-emitting device may emit light in a pulsed manner to display an image. A reduction in the driving time of the light-emitting device can reduce the power consumption of the display device and inhibit heat generation.

Here, a transistor including a metal oxide (an oxide semiconductor) in a semiconductor layer where a channel is formed is preferably used as each of the transistors included in the circuits PIX1 and PIX2.

A transistor including a metal oxide having a wider band gap and a lower carrier density than silicon achieves an extremely low off-state current. Owing to the low off-state current, charge accumulated in a capacitor element that is connected in series with the transistor can be retained for a long time.

That is, since data can be retained for a long time, image display can be maintained even when the frame frequency is decreased to, for example, lower than or equal to 1 Hz. Lowering the frame frequency can reduce the power consumption needed for data rewriting, achieving lower power consumption of the display device. Being able to lower the frame frequency is also effective for foveated rendering.

Note that although FIG. 6A to FIG. 6D each illustrate an example in which n-channel transistors are used, p-channel transistors can also be used.

When the display device is manufactured using one embodiment of the present invention described above, the display device can have a narrow bezel, high performance, and high operation speed.

At least part of this embodiment can be implemented in combination with the other embodiments described in this specification as appropriate.

### Embodiment 2

In this embodiment, a vertical transistor corresponding to the first OS transistor shown in Embodiment 1 will be described.

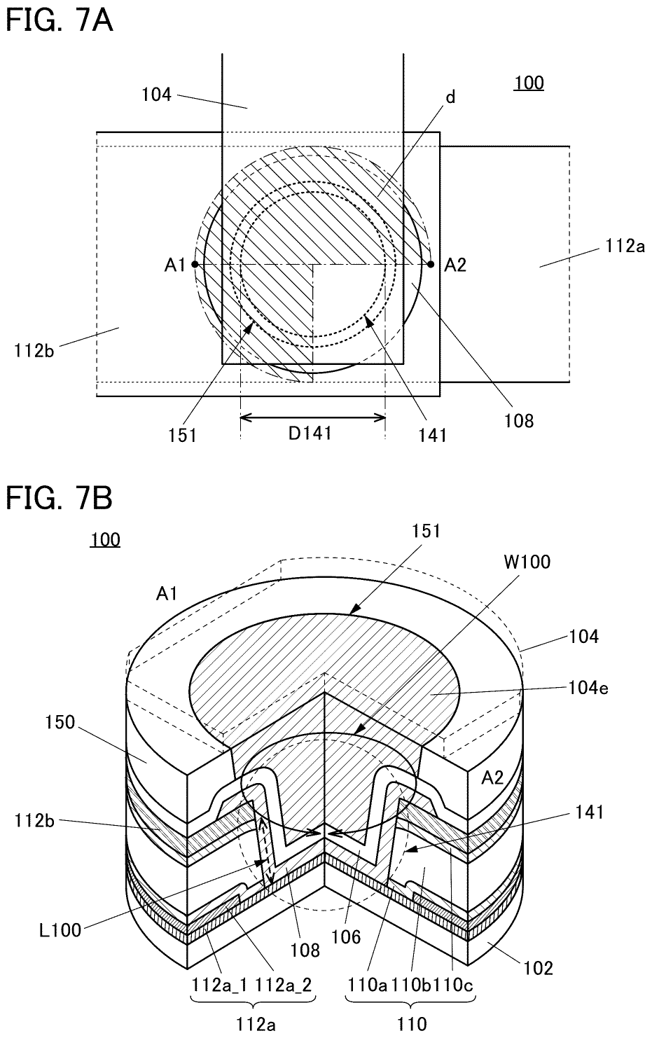

FIG. 7A and FIG. 7B are diagrams illustrating a vertical transistor. FIG. 7A is a top view. FIG. 7B is a cross-sectional perspective view in the depth direction of a region d illustrated in FIG. 7A. Note that for simplification, some components are not illustrated in FIG. 7A. In FIG. 7B, a conductive layer 104 is denoted by a dashed line.

A vertical transistor 100 can be provided over a substrate 102. Note that in the case where the transistor 100 is formed in the layer 30a described in Embodiment 1, the substrate 102 corresponds to the layer 20.

The transistor 100 includes the conductive layer 104, a conductive layer 104e, an insulating layer 106, a semiconductor layer 108, a conductive layer 112a, and a conductive layer 112b. The conductive layer 104 is a gate wiring electrically connected to the conductive layer 104e functioning as a gate electrode. Part of the insulating layer 106 functions as a gate insulating layer. The conductive layer 112a functions as one of a source electrode and a drain electrode. The conductive layer 112b functions as the other of the source electrode and the drain electrode.

In the semiconductor layer 108, the whole region that is between the source electrode and the drain electrode and overlaps with the gate electrode with the gate insulating layer therebetween functions as a channel formation region. In the semiconductor layer 108, a region in contact with the source electrode functions as a source region, and a region in contact with the drain electrode functions as a drain region.

The conductive layer 112a is provided over the substrate 102, an insulating layer 110 is provided over the conductive layer 112a, and the conductive layer 112b is provided over the insulating layer 110. The insulating layer 110 includes a region interposed between the conductive layer 112a and the conductive layer 112b. The conductive layer 112a includes a region overlapping with the conductive layer 112b with the insulating layer 110 therebetween. An opening 141 reaching the conductive layer 112a is provided in the insulating layer 110 and the conductive layer 112b.

The conductive layer 112a and the conductive layer 112b may each have a stacked-layer structure. FIG. 7B and the like illustrate an example in which the conductive layer 112a has a stacked-layer structure of a conductive layer 112a_1 and a conductive layer 112a_2. Note that although FIG. 7B illustrates an example in which the conductive layer 112a_1 includes a region over which the conductive layer 112a_2 is not provided and the region is in contact with the semiconductor layer 108, the conductive layer 112a_2 may be in contact with the semiconductor layer 108.

The top-surface shape of the opening 141 can be a circle or an ellipse, for example. When the top-surface shape of the opening 141 is a circle, the opening 141 can be formed with high processing accuracy and the opening 141 having a minute size can be formed. Note that the top-surface shape of the opening 141 may be a polygon such as a triangle, a tetragon (including a rectangle, a rhombus, and a square), or a pentagon, or a polygon with rounded corners. The opening 141 can be formed using a resist mask, for example.

The semiconductor layer 108 is provided to cover the opening 141. The semiconductor layer 108 includes a region in contact with a top surface and a side surface of the conductive layer 112b, a side surface of the insulating layer 110, and a top surface of the conductive layer 112a. The semiconductor layer 108 is electrically connected to the conductive layer 112a through the opening 141. The semiconductor layer 108 has a shape along the shapes of the top surface and the side surface of the conductive layer 112b, the side surface of the insulating layer 110, and the top surface of the conductive layer 112a.

Although the semiconductor layer 108 has a single-layer structure in FIG. 7B and the like, one embodiment of the present invention is not limited thereto. The semiconductor layer 108 may have a stacked-layer structure of two or more layers.

The insulating layer 106 functioning as the gate insulating layer of the transistor 100 is provided over the semiconductor layer 108, the conductive layer 112b, and the insulating layer 110 to cover a depressed portion originating from the opening 141.

The conductive layer 104e of the transistor 100 is provided over the insulating layer 106 to cover the depressed portion originating from the opening 141. Here, an insulating layer 150 including the opening 141 and an opening 151 reaching the insulating layer 106 is preferably provided over the insulating layer 106.

The insulating layer 150 can be used as an insulating layer for forming an embedded electrode by a damascene process. That is, the conductive layer 104e is provided over the insulating layer 106 to fill the depressed portion originating from the opening 141 and the opening 151 included in the insulating layer 150. The conductive layer 104 can be formed over the conductive layer 104e and the insulating layer 150 that have been planarized in a damascene process.

The conductive layer 104e includes a region overlapping with the semiconductor layer 108 with the insulating layer 106 therebetween in the opening 141. The conductive layer 104e also includes a region overlapping with the conductive layer 112a and a region overlapping with the conductive layer 112b with the insulating layer 106 and the semiconductor layer 108 therebetween. The conductive layer 104e preferably covers an end portion of the conductive layer 112b on the opening 141 side. With such a structure, in the semiconductor layer 108, the whole region that is between the source electrode and the drain electrode and overlaps with the gate electrode with the gate insulating layer therebetween can function as a channel formation region.

The transistor 100 is what is called a top-gate transistor including the gate electrode above the semiconductor layer 108. Furthermore, since a bottom surface of the semiconductor layer 108 is in contact with the source electrode or the drain electrode, the transistor 100 can be referred to as a TGBC (Top Gate Bottom Contact) transistor.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. This can reduce the area occupied by the circuit.

In the transistor of one embodiment of the present invention, the conductive layer 112a, the conductive layer 112b, the conductive layer 104, and the conductive layer 112b functioning as wirings can be provided by processing different conductive films. Thus, any one of the conductive layers can be provided to overlap with at least one of the other conductive layers, leading to high layout flexibility and a reduction in the area occupied by the circuit.

Next, the channel length and the channel width of the transistor 100 will be described. In the semiconductor layer 108, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 100 is the distance between the source region and the drain region. In FIG. 7B, a channel length L100 of the transistor 100 is indicated by a dashed double-headed arrow. In the cross-sectional view, the channel length L100 is the distance between an end portion of the region where the semiconductor layer 108 is in contact with the conductive layer 112a and an end portion of the region where the semiconductor layer 108 is in contact with the conductive layer 112b.

That is, the channel length L100 is determined by the thickness of the insulating layer 110 and the angle formed by the side surface of the insulating layer 110 on the opening 141 side and the top surface of the conductive layer 112a, and is not affected by the performance of a light-exposure apparatus used for manufacturing the transistor. Thus, the channel length L100 can be a value smaller than that of the resolution limit of a light-exposure apparatus, which enables a transistor having a minute size.

The reduction in the channel length L100 can increase the on-state current of the transistor 100. With use of the transistor 100, a circuit capable of high-speed operation can be manufactured. Furthermore, the transistor can be downsized, which enables a reduction in the area occupied by the circuit.

Although FIG. 7B and the like illustrate the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region.

The channel width of the transistor 100 is the width of the source region or the width of the drain region in a direction orthogonal to the channel length direction. In other words, the channel width is the width of the region where the semiconductor layer 108 is in contact with the conductive layer 112a or the width of the region where the semiconductor layer 108 is in contact with the conductive layer 112b in the direction orthogonal to the channel length direction. Here, the channel width of the transistor 100 is described as the width of the region where the semiconductor layer 108 is in contact with the conductive layer 112b in the direction orthogonal to the channel length direction. In FIG. 7A and FIG. 7B, a channel width W100 of the transistor 100 is indicated by a solid double-headed arrow. In the top view, the channel width W100 is the length of the end portion of the bottom surface of the conductive layer 112b on the opening 141 side.

The channel width W100 is determined by the top-surface shape of the opening 141. Note that in the case where the top surface shape of the opening 141 is a circle, the channel width W100 can be calculated to be “D141×π” assuming that the diameter of the opening 141 is D141 and the thickness of the conductive layer 112b is negligible.

In other words, it can be said that the transistor 100 has a large channel width with respect to its occupation area. The transistor 100 with a large channel width W100 can have a high on-state current and thus a circuit capable of high-speed operation can be manufactured.

Components included in the transistor 100 of this embodiment will be described below.

### [Components of Transistor]

### [Semiconductor Layer 108]

A semiconductor material that can be used for the semiconductor layer 108 is not particularly limited. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for the semiconductor layer 108, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case deterioration of the transistor characteristics can be inhibited.

The semiconductor layer 108 preferably includes a metal oxide (an oxide semiconductor). Examples of the metal oxide that can be used for the semiconductor layer 108 include indium oxide, gallium oxide, and zinc oxide. The metal oxide preferably contains at least indium (In) or zinc (Zn). The metal oxide preferably contains two or three kinds selected from indium, an element M, and zinc. The element M is one or more kinds selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more kinds selected from aluminum, gallium, yttrium, and tin. The element M is further preferably gallium.

For the semiconductor layer 108, for example, any of indium oxide, indium gallium oxide (In—Ga oxide), indium zinc oxide (In—Zn oxide), indium tin oxide (In—Sn oxide), indium titanium oxide (In—Ti oxide), gallium zinc oxide (Ga—Zn oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), and indium gallium aluminum zinc oxide (In—Ga—Al—Zn oxide, also referred to as IGAZO or IAGZO) can be used. Alternatively, indium tin oxide containing silicon, or the like can also be used.

Here, the composition of the metal oxide included in the semiconductor layer 108 greatly affects the electrical characteristics and reliability of the transistor 100. For example, by increasing the proportion of the number of indium atoms in the total number of atoms of all the metal elements contained in the metal oxide, a transistor having a high on-state current can be provided.

In the case of using In—Zn oxide for the semiconductor layer 108, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case of using In—Sn oxide for the semiconductor layer 108, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In—Sn—Zn oxide for the semiconductor layer 108, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In—Al—Zn oxide for the semiconductor layer 108, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In—Ga—Zn oxide for the semiconductor layer 108, a metal oxide in which the proportion of the number of indium atoms in the total number of atoms of all the contained metal elements is higher than the proportion of the number of gallium atoms can be used. It is further preferable to use a metal oxide in which the proportion of the number of zinc atoms is higher than the proportion of the number of gallium atoms. For example, a metal oxide having any of the following atomic ratios of metal elements can be used for the semiconductor layer 108: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

In the case of using In-M-Zn oxide for the semiconductor layer 108, a metal oxide in which the proportion of the number of indium atoms in the total number of atoms of all the contained metal elements is higher than the proportion of the number of element M atoms can be used. It is further preferable to use a metal oxide in which the proportion of the number of zinc atoms is higher than the proportion of the number of element M atoms. For example, a metal oxide having any of the following atomic ratios of metal elements can be used for the semiconductor layer 108: InM:Zn=2:1:3, InM:Zn=3:1:2, InM:Zn=4:2:3, InM:Zn=4:2:4.1, InM:Zn=5:1:3, InM:Zn=5:1:6, InM:Zn=5:1:7, InM:Zn=5:1:8, In:M:Zn=6:1:6, InM:Zn=10:1:3, InM:Zn=10:1:6, InM:Zn=10:1:7, InM:Zn=10:1:8, InM:Zn=5:2:5, InM:Zn=10:1:10, InM:Zn=20:1:10, InM:Zn=40:1:10, and the neighborhood thereof.

A higher indium content percentage in the metal oxide enables the transistor to have a high on-state current. By using such a transistor as a transistor requiring a high on-state current, a circuit having excellent electrical characteristics can be formed.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

Note that a composition in the neighborhood in this specification and the like includes the range of ±30% of an intended atomic ratio. For example, when the atomic ratio is described as InM:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as InM:Zn=5:1:6 or a composition in the neighborhood thereof, the case is included where the atomic ratio of the element M is greater than 0.1 and less than or equal to 2 and the atomic ratio of zinc is greater than or equal to 5 and less than or equal to 7 with the atomic ratio of indium being 5. When the atomic ratio is described as InM:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

The semiconductor layer 108 may have a stacked-layer structure including two or more metal oxide layers. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 108 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer 108. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer 108, the density of defect states in the semiconductor layer 108 can be reduced, which enables the transistor to have high reliability.

The higher the crystallinity of the metal oxide layer used as the semiconductor layer 108 is, the lower the density of defect states in the semiconductor layer 108 can be. By contrast, the use of a metal oxide layer having low crystallinity enables a transistor to flow a large amount of current.

The semiconductor layer 108 may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer 108 may have different compositions.

When an oxide semiconductor is used for the semiconductor layer 108, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm³.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter also referred to as off-state current), and charge accumulated in a capacitor that is connected in series with the transistor can be held for a long period. Furthermore, the power consumption of the semiconductor device can be reduced with the OS transistor.

### [Insulating Layer 110]

In the case where an oxide semiconductor is used for the semiconductor layer 108, an inorganic insulating material can be suitably used for the insulating layer 110 (an insulating layer 110a, an insulating layer 110b, and an insulating layer 110c. Note that the insulating layer 110 may have a stacked-layer structure of an inorganic insulating material and an organic insulating material.

As the inorganic insulating material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

It is preferable to use an oxide or an oxynitride for the insulating layer 110b. A film from which oxygen is released by heating is preferably used as the insulating layer 110b. For example, silicon oxide or silicon oxynitride can be suitably used for the insulating layer 110b.

Oxygen released from the insulating layer 110b can be supplied to the semiconductor layer 108. Supplying oxygen from the insulating layer 110b to the semiconductor layer 108, particularly to the channel formation region in the semiconductor layer 108, can reduce the amount of oxygen vacancy (V_{O}) and V_{O}H (defect in which hydrogen enters oxygen vacancy) in the semiconductor layer 108, so that a highly reliable transistor having favorable electrical characteristics can be obtained. The insulating layer 110b preferably has a high oxygen diffusion coefficient. When the insulating layer 110b has a high oxygen diffusion coefficient, oxygen is easily diffused in the insulating layer 110b, so that oxygen can be efficiently supplied from the insulating layer 110b to the semiconductor layer 108. Examples of treatment for supplying oxygen to the semiconductor layer 108 include heat treatment in an oxygen-containing atmosphere and plasma treatment in an oxygen-containing atmosphere.

It is preferable that the amount of oxygen vacancy (V_{O}) and V_{O}H be small in the channel formation region of the transistor 100. Particularly in the case where the channel length L100 is short, oxygen vacancy (V_{O}) and V_{O}H in the channel formation region greatly affect electrical characteristics and reliability. For example, diffusion of V_{O}H from the source region or the drain region into the channel formation region increases the carrier concentration in the channel formation region, which might cause a change in the threshold voltage or a reduction in the reliability in the transistor 100. As the channel length L100 of the transistor 100 is shorter, such diffusion of V_{O}H greatly affects electrical characteristics and reliability. Supplying oxygen from the insulating layer 110b to the semiconductor layer 108, particularly to the channel formation region in the semiconductor layer 108, can reduce the amount of oxygen vacancy (V_{O}) and V_{O}H. Thus, the transistor with a short channel length can have favorable electrical characteristics and high reliability.

The insulating layer 110a and the insulating layer 110c are preferably less likely to transmit oxygen. The insulating layer 110a and the insulating layer 110c function as blocking films that inhibit release of oxygen from the insulating layer 110b. Moreover, the insulating layer 110a and the insulating layer 110c are preferably less likely to transmit hydrogen. The insulating layer 110a and the insulating layer 110c function as blocking films that inhibit diffusion of hydrogen into the semiconductor layer 108 from the outside of the transistor through the insulating layer 110. The insulating layer 110a and the insulating layer 110c preferably have high film densities. The insulating layer 110a and the insulating layer 110c having high film densities can have a high blocking property against oxygen and hydrogen. The film densities of the insulating layer 110a and the insulating layer 110c are preferably higher than the film density of the insulating layer 110b. In the case where silicon oxide or silicon oxynitride is used for the insulating layer 110b, silicon nitride, silicon nitride oxide, or aluminum oxide can be suitably used for each of the insulating layer 110a and the insulating layer 110c, for example. The insulating layer 110a and the insulating layer 110c each preferably include a region containing more nitrogen than the insulating layer 110b. A material containing more nitrogen than the insulating layer 110b can be used for each of the insulating layer 110a and the insulating layer 110c. A nitride or a nitride oxide is preferably used for each of the insulating layer 110a and the insulating layer 110c. For example, silicon nitride or silicon nitride oxide can be suitably used for each of the insulating layer 110a and the insulating layer 110c.

When oxygen contained in the insulating layer 110b is diffused upward from a region of the insulating layer 110b that is not in contact with the semiconductor layer 108 (e.g., a top surface of the insulating layer 110b), the amount of oxygen supplied from the insulating layer 110b to the semiconductor layer 108 might be reduced. Provision of the insulating layer 110c over the insulating layer 110b can inhibit diffusion of oxygen contained in the insulating layer 110b from the region of the insulating layer 110 that is not in contact with the semiconductor layer 108. Similarly, provision of the insulating layer 110a under the insulating layer 110b can inhibit downward diffusion of oxygen from the region of the insulating layer 110 that is not in contact with the semiconductor layer 108. Accordingly, the amount of oxygen supplied from the insulating layer 110b to the semiconductor layer 108 is increased, whereby the amount of oxygen vacancy (V_{O}) and V_{O}H in the semiconductor layer 108 can be reduced. Consequently, the transistor can have favorable electrical characteristics and high reliability.

The conductive layer 112a and the conductive layer 112b are oxidized by oxygen contained in the insulating layer 110b and have high resistance in some cases. Moreover, when the conductive layer 112a and the conductive layer 112b are oxidized by oxygen contained in the insulating layer 110b, the amount of oxygen supplied from the insulating layer 110b to the semiconductor layer 108 might be reduced. Provision of the insulating layer 110a between the insulating layer 110b and the conductive layer 112a can inhibit the conductive layer 112a from being oxidized and having high resistance. Similarly, provision of the insulating layer 110c between the insulating layer 110b and the conductive layer 112b can inhibit the conductive layer 112b from being oxidized and having high resistance. In addition, the amount of oxygen supplied from the insulating layer 110b to the semiconductor layer 108 is increased and the amount of oxygen vacancy (V_{O}) and V_{O}H in the semiconductor layer 108 can be reduced, whereby the transistor can have favorable electric characteristics and high reliability.

Hydrogen diffused in the semiconductor layer 108 reacts with an oxygen atom contained in an oxide semiconductor to be water, and thus sometimes forms oxygen vacancy (V_{O}). Furthermore, V_{O}H is formed and the carrier density is increased in some cases. Provision of the insulating layer 110a and the insulating layer 110c can reduce the amount of oxygen vacancy (V_{O}) and V_{O}H in the semiconductor layer 108, whereby the transistor can have favorable electric characteristics and high reliability.

The insulating layer 110a and the insulating layer 110c preferably have thicknesses with which the insulating layers function as blocking films against oxygen and hydrogen. When the insulating layer 110a and the insulating layer 110c are thin, the function of a blocking film might deteriorate. Meanwhile, when the insulating layer 110a and the insulating layer 110c are thick, a region where the semiconductor layer 108 is in contact with the insulating layer 110b is narrowed and the amount of oxygen supplied from the insulating layer 110b to the semiconductor layer 108 might be reduced. The insulating layer 110a and the insulating layer 110c may each be thinner than the insulating layer 110b.

In the transistor 100, oxygen is supplied from the insulating layer 110 to the semiconductor layer 108, whereby the amount of oxygen vacancy (V_{O}) and V_{O}H in the channel formation region is reduced. Consequently, the transistor can have favorable electrical characteristics and high reliability.

Note that one or both of the insulating layer 110a and the insulating layer 110c are not necessarily provided.

[Conductive Layer 112a, Conductive Layer 112b, and Conductive Layer 104e]

The conductive layer 112a, the conductive layer 112b, and the conductive layer 104e functioning as a source electrode, a drain electrode, and a gate electrode can each be formed using one or more of chromium, copper, aluminum, gold, silver, zinc, tantalum, titanium, tungsten, manganese, nickel, iron, cobalt, molybdenum, and niobium; or an alloy including one or more of these metals as its components. For each of the conductive layer 112a, the conductive layer 112b, and the conductive layer 104e, a conductive material with low resistance that contains one or more of copper, silver, gold, and aluminum can be suitably used. Copper or aluminum is particularly preferable because of its high mass-productivity.

As the conductive layer 112a, the conductive layer 112b, and the conductive layer 104e, metal oxide films (also referred to as oxide conductors) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when oxygen vacancy is formed in a metal oxide having semiconductor characteristics and hydrogen is added to the oxygen vacancy, a donor level is formed in the vicinity of the conduction band. As a result, the conductivity of the metal oxide is increased, so that the metal oxide becomes a conductor. The metal oxide having become a conductor can be referred to as an oxide conductor.

Each of the conductive layer 112a, the conductive layer 112b, and the conductive layer 104e may have a stacked-layer structure of a conductive film containing the oxide conductor (the metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, and the conductive layer 104e. The use of a Cu—X alloy film enables the manufacturing cost to be reduced because a wet etching method can be used in the processing.

Note that the conductive layer 112a, the conductive layer 112b, and the conductive layer 104e may be formed using the same material or different materials.

Here, the conductive layer 112a and the conductive layer 112b will be described in detail with use of a structure in which a metal oxide is used for the semiconductor layer 108 as an example.

When an oxide semiconductor is used for the semiconductor layer 108, the conductive layer 112a and the conductive layer 112b are oxidized by oxygen contained in the semiconductor layer 108 and have high resistance in some cases. The conductive layer 112a and the conductive layer 112b are oxidized by oxygen contained in the insulating layer 110b and have high resistance in some cases. Moreover, when the conductive layer 112a and the conductive layer 112b are oxidized by oxygen contained in the semiconductor layer 108, the amount of oxygen vacancy (V_{O}) in the semiconductor layer 108 is increased in some cases. When the conductive layer 112a and the conductive layer 112b are oxidized by oxygen contained in the insulating layer 110b, the amount of oxygen supplied from the insulating layer 110b to the semiconductor layer 108 might be reduced.

A material that is less likely to be oxidized is preferably used for each of the conductive layer 112a and the conductive layer 112b. An oxide conductor is preferably used for each of the conductive layer 112a and the conductive layer 112b. For example, In—Sn oxide (ITO) or In—Sn—Si oxide (ITSO) can be suitably used. A nitride conductor may be used for the conductive layer 112a. Examples of the nitride conductor include tantalum nitride and titanium nitride. The conductive layer 112a may have a stacked-layer structure of the above-described materials.

The conductive layer 112a and the conductive layer 112b each containing a material that is less likely to be oxidized can be inhibited from being oxidized by oxygen contained in the semiconductor layer 108 or oxygen contained in the insulating layer 110b and having high resistance. Furthermore, it is possible to increase the amount of oxygen supplied from the insulating layer 110b to the semiconductor layer 108 while an increase in the amount of oxygen vacancy (V_{O}) in the semiconductor layer 108 is inhibited. Accordingly, the amount of oxygen vacancy (V_{O}) and V_{O}H in the semiconductor layer 108 can be reduced, whereby the transistor can have favorable electric characteristics and high reliability.

Similarly, the conductive layer 112b containing a material that is less likely to be oxidized can be inhibited from having high resistance. Note that the conductive layer 112a and the conductive layer 112b may be formed using the same material or different materials.

The conductive layer 112b has a region in contact with the transistor 100. When a material that is less likely to be oxidized is used for the conductive layer 112b, the amount of oxygen vacancy (V_{O}) and V_{O}H in the semiconductor layer 108 can be reduced.

As described above, a material that is less likely to be oxidized is preferably used for each of the conductive layer 112a and the conductive layer 112b in contact with the semiconductor layer 108. However, the use of a material that is less likely to be oxidized might increase resistance. The conductive layer 112a and the conductive layer 112b function as wirings and thus preferably have low resistance. In view of this, a material that is less likely to be oxidized is used for the conductive layer 112a_1 including a region in contact with the semiconductor layer 108, and a material with low resistance is used for the conductive layer 112a_2 not including a region in contact with the semiconductor layer 108, whereby the resistance of the conductive layer 112a can be reduced. Furthermore, the amount of oxygen vacancy (V_{O}) and V_{O}H in the semiconductor layer 108 can be reduced, whereby the transistor can have favorable electric characteristics and high reliability.

In particular, in the case where the channel length L100 is short, oxygen vacancy (V_{O}) and V_{O}H in the channel formation region greatly affect electrical characteristics and reliability, as described above. When a material that is less likely to be oxidized is used for the conductive layer 112a_1, an increase in the amount of oxygen vacancy (V_{O}) and V_{O}H in the semiconductor layer 108 can be inhibited. Thus, the transistor with a short channel length can have favorable electrical characteristics and high reliability.

One or more of an oxide conductor and a nitride conductor can be suitably used for the conductive layer 112a_1. For the conductive layer 112a_2, a material having lower resistance than the conductive layer 112a_1 is preferably used. For the conductive layer 112a_2, one or more of copper, aluminum, titanium, tungsten, and molybdenum or an alloy containing one or more of these metals as its components can be suitably used, for example. Specifically, In—Sn—Si oxide (ITSO) and tungsten can be suitably used for the conductive layer 112a_1 and the conductive layer 112a_2, respectively.

Note that the structure of the conductive layer 112a is determined in accordance with wiring resistance required for the conductive layer 112a. For example, when the wiring (the conductive layer 112a) is short and requires relatively high wiring resistance, the conductive layer 112a may have a single-layer structure using a material that is less likely to be oxidized. Meanwhile, when the wiring (the conductive layer 112a) is long and requires relatively low wiring resistance, the conductive layer 112a preferably has a stacked-layer structure using a material that is less likely to be oxidized and a material with low resistance.

The structure of the conductive layer 112a can be applied to another conductive layer.

### [Insulating Layer 106]

The insulating layer 106 functioning as the gate insulating layer preferably has low defect density. With the insulating layer 106 having low defect density, the transistor can have favorable electrical characteristics. In addition, the insulating layer 106 preferably has high withstand voltage. With the insulating layer 106 having high withstand voltage, the transistor can have high reliability.

For the insulating layer 106, one or more of an insulating oxide, an insulating oxynitride, an insulating nitride oxide, and an insulating nitride can be used, for example. For the insulating layer 106, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 106 may be either a single layer or a stacked layer. The insulating layer 106 may have a stacked-layer structure of an oxide and a nitride.

A transistor having a minute size and including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 itself is preferably small. With the insulating layer 106 from which a small amount of impurities is released, diffusion of impurities into the semiconductor layer 108 is inhibited, and the transistor can have favorable electrical characteristics and high reliability.

Here, the insulating layer 106 will be described in detail with use of a structure in which a metal oxide is used for the semiconductor layer 108 as an example.

To improve the properties of the interface with the semiconductor layer 108, at least the side of a region in the insulating layer 106, which is in contact with the semiconductor layer 108, preferably includes an oxide. For example, one or more of silicon oxide and silicon oxynitride can be suitably used for the insulating layer 106. A film from which oxygen is released by heating is further preferably used for the insulating layer 106.

Note that the insulating layer 106 may have a stacked-layer structure. The insulating layer 106 can have a stacked-layer structure of an oxide film on the side in contact with the semiconductor layer 108 and a nitride film on the side in contact with the conductive layer 104e. For example, one or more of silicon oxide and silicon oxynitride can be suitably used for the oxide film. Silicon nitride can be suitably used for the nitride film.

### [Insulating Layer 150]

A material similar to that for the insulating layer 110 can be used for the insulating layer 150. The insulating layer 150 is preferably formed using a material that has high etching selectivity with respect to the insulating layer 106 and is more easily etched than the material for the insulating layer 106. Note that FIG. 7B illustrates an example in which the insulating layer 150 is a single layer, but the insulating layer 150 may have a two-layer structure.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In such a case, the transistor 100 and the like can be transferred to a substrate having low heat resistance or a flexible substrate as well.

The above is the description of the components of the transistor 100.

At least part of this embodiment can be implemented in combination with the other embodiments described in this specification as appropriate.

### Embodiment 3

In this embodiment, structure examples of a display panel that can be employed for the electronic device of one embodiment of the present invention will be described. A display panel described below as an example can be employed for the display device 10 in Embodiment 1.

One embodiment of the present invention is a display panel including light-emitting elements (also referred to as light-emitting devices). The display panel includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers containing different light-emitting materials. For example, when three kinds of light-emitting elements that emit red (R), green (G), and blue (B) light are included, a full-color display panel can be achieved.

In the case of manufacturing a display panel including a plurality of light-emitting elements of different emission colors, at least layers (light-emitting layers) containing light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display panel. In addition, the outline of the layer might blur during evaporation, so that the thickness of an end portion might be reduced. That is, the thickness of an island-shaped light-emitting layer might vary from place to place. In addition, in the case of manufacturing a display panel with a large size, a high definition, or a high resolution, a manufacturing yield might be reduced because of low dimensional accuracy of the metal mask and deformation due to heat or the like. Thus, a measure has been taken for a pseudo increase in resolution (also referred to as pixel density) by employing unique pixel arrangement such as PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by a photolithography method without using a shadow mask such as a fine metal mask (FMM). Accordingly, it is possible to achieve a display panel with a high resolution and a high aperture ratio, which has been difficult to achieve. Moreover, since the EL layers can be formed separately, it is possible to achieve a display panel that performs extremely clear display with high contrast and high display quality. Note that, fine patterning of the EL layers may be performed using both a metal mask and a photolithography method, for example.

In addition, part or the whole of the EL layer can be physically divided from each other. This can inhibit leakage current flowing between adjacent light-emitting elements through a layer (also referred to as a common layer) shared by the light-emitting elements. Thus, it is possible to prevent crosstalk due to unintended light emission, so that a display panel with extremely high contrast can be achieved. In particular, a display panel having high current efficiency at low luminance can be achieved.

In one embodiment of the present invention, the display panel can be also obtained by combining a light-emitting element that emits white light with a color filter. In that case, light-emitting elements having the same structure can be used as light-emitting elements provided in pixels (subpixels) that emit light of different colors, which allows all the layers to be common layers. In addition, part or the whole of the EL layer may be divided from each other in a step using a photolithography method. Thus, leakage current through the common layer is inhibited; accordingly, a high-contrast display panel can be achieved. In particular, when an element has a tandem structure where a plurality of light-emitting layers are stacked with a highly conductive intermediate layer therebetween, leakage current through the intermediate layer can be effectively prevented, so that a display panel with high luminance, high resolution, and high contrast can be achieved.

In the case where the EL layer is processed by a lithography method, part of the light-emitting layer is sometimes exposed to cause degradation. Thus, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display panel.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as LFP: Local Filling Planarization) functioning as a planarization film. The resin layer has a function of a planarization film. This structure can inhibit disconnection of the common layer or the common electrode and can achieve a highly reliable display panel.

More specific structure examples of the display panel of one embodiment of the present invention will be described below with reference to drawings.

### Structure Example 1

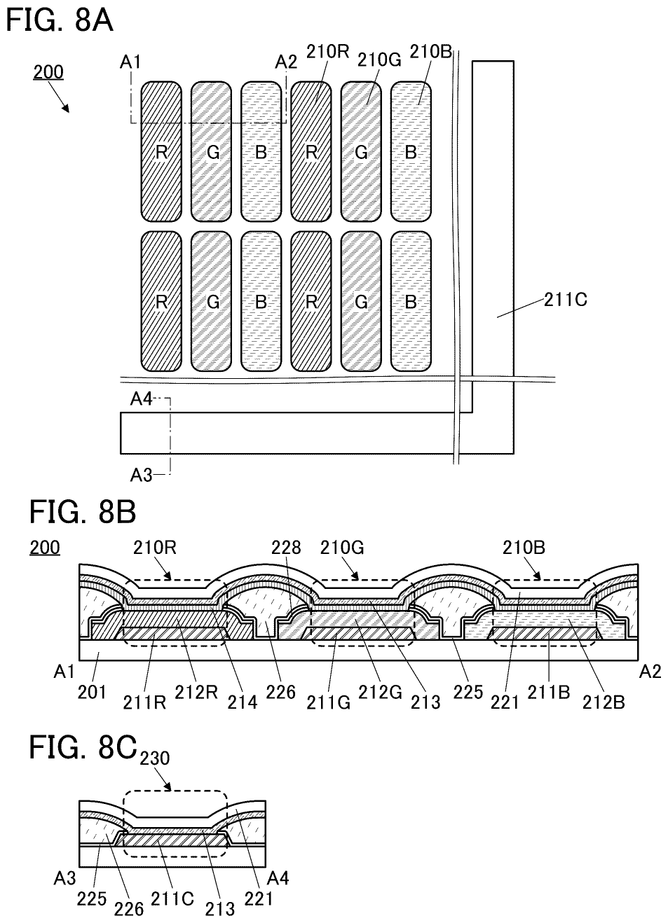

FIG. 8A is a schematic top view of a display panel 200 of one embodiment of the present invention. The display panel 200 includes, over a layer 201, a plurality of light-emitting elements 210R exhibiting red, a plurality of light-emitting elements 210G exhibiting green, and a plurality of light-emitting elements 210B exhibiting blue. In FIG. 8A, light-emitting regions of the light-emitting elements are denoted by R, G, and B to easily differentiate the light-emitting elements. Note that the layer 201 can be a component included in the layer 30b or the like shown in Embodiment 1.

The light-emitting elements 210R, the light-emitting elements 210G, and the light-emitting elements 210B are each arranged in a matrix. FIG. 8A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can be also used.

As each of the light-emitting elements 210R, the light-emitting elements 210G, and the light-emitting elements 210B, an OLED (Organic Light Emitting Diode) or a QLED (Quantum-dot Light Emitting Diode) is preferably used, for example. As a light-emitting substance contained in the EL element, a substance that emits fluorescent light (a fluorescent material), a substance that emits phosphorescent light (a phosphorescent material), and a substance that exhibits thermally activated delayed fluorescence (a thermally activated delayed fluorescent (Thermally activated delayed fluorescence: TADF) material) can be given, for example. As the light-emitting substance contained in the EL element, not only an organic compound but also an inorganic compound (a quantum dot material or the like) can be used.

FIG. 8A also illustrates a connection electrode 211C that is electrically connected to a common electrode 213. The connection electrode 211C is supplied with a potential (e.g., an anode potential or a cathode potential) that is to be supplied to the common electrode 213. The connection electrode 211C is provided outside a display region where the light-emitting elements 210R and the like are arranged.

The connection electrode 211C can be provided along the outer periphery of the display region. For example, the connection electrode 211C may be provided along one side of the outer periphery of the display region, or the connection electrode 211C may be provided along two or more sides of the outer periphery of the display region. That is, in the case where the display region has a rectangular top surface shape, the top surface shape of the connection electrode 211C can be a band shape (a rectangle), an L shape, a U shape (a square bracket shape), a quadrangular shape, or the like.

FIG. 8B and FIG. 8C are schematic cross-sectional views corresponding to the dashed-dotted line A1-A2 and the dashed-dotted line A3-A4 in FIG. 8A. FIG. 8B is a schematic cross-sectional view of the light-emitting element 210R, the light-emitting element 210G, and the light-emitting element 210B, and FIG. 8C is a schematic cross-sectional view of a connection portion 230 where the connection electrode 211C and the common electrode 213 are connected to each other.

The light-emitting element 210R includes a pixel electrode 211R, an organic layer 212R, a common layer 214, and the common electrode 213. The light-emitting element 210G includes a pixel electrode 211G, an organic layer 212G, the common layer 214, and the common electrode 213. The light-emitting element 210B includes a pixel electrode 2111B, an organic layer 212B, the common layer 214, and the common electrode 213. The common layer 214 and the common electrode 213 are provided to be shared by the light-emitting element 210R, the light-emitting element 210G, and the light-emitting element 210B.

The organic layer 212R included in the light-emitting element 210R contains at least a light-emitting organic compound that emits red light. The organic layer 212G included in the light-emitting element 210G contains at least a light-emitting organic compound that emits green light. The organic layer 212B included in the light-emitting element 210B contains at least a light-emitting organic compound that emits blue light. Each of the organic layer 212R, the organic layer 212G, and the organic layer 212B can be also referred to as an EL layer and includes at least a layer containing a light-emitting substance (a light-emitting layer).

Hereinafter, the term “light-emitting element 210” is sometimes used to describe matters common to the light-emitting element 210R, the light-emitting element 210G, and the light-emitting element 210B. Similarly, in the description of matters common to components that are distinguished from each other using alphabets, such as the organic layer 212R, the organic layer 212G, and the organic layer 212B, reference numerals without alphabets are sometimes used.

Each of the organic layer 212 and the common layer 214 can independently include one or more of an electron-injection layer, an electron-transport layer, a hole-injection layer, and a hole-transport layer. For example, it is possible to employ a structure where the organic layer 212 has a stacked-layer structure of a hole-injection layer, a hole-transport layer, a light-emitting layer, and an electron-transport layer from the pixel electrode 211 side and the common layer 214 includes an electron-injection layer.

The pixel electrode 211R, the pixel electrode 211G, and the pixel electrode 211B are provided for the respective light-emitting elements. In addition, the common electrode 213 and the common layer 214 are each provided as a continuous layer shared by the light-emitting elements. A conductive film having a light-transmitting property with respect to visible light is used for either the pixel electrodes or the common electrode 213, and a conductive film having a reflective property is used for the other. When the pixel electrodes have light-transmitting properties and the common electrode 213 has a reflective property, a bottom-emission display panel can be obtained. In contrast, when the pixel electrodes have reflective properties and the common electrode 213 has a light-transmitting property, a top-emission display panel can be obtained. Note that when both the pixel electrodes and the common electrode 213 have light-transmitting properties, a dual-emission display panel can be obtained.

A protective layer 221 is provided over the common electrode 213 to cover the light-emitting element 210R, the light-emitting element 210G, and the light-emitting element 210B. The protective layer 221 has a function of preventing diffusion of impurities such as water into each light-emitting element from the above.

An end portion of the pixel electrode 211 preferably has a tapered shape. In the case where the end portion of the pixel electrode 211 has a tapered shape, the organic layer 212 that is provided along the end portion of the pixel electrode 211 can also have a tapered shape. When the end portion of the pixel electrode 211 has a tapered shape, coverage with the organic layer 212 provided beyond the end portion of the pixel electrode 211 can be increased. Furthermore, when the side surface of the pixel electrode 211 has a tapered shape, a material (for example, also referred to as dust or particles) in a manufacturing step is easily removed by processing such as cleaning, which is preferable.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

The organic layer 212 is processed into an island shape by a photolithography method. Thus, the angle formed between a top surface and a side surface of an end portion of the organic layer 212 is approximately 90°. In contrast, an organic film formed using an FMM (Fine Metal Mask) or the like tends to have a thickness that gradually decreases with decreasing distance from an end portion, and has a top surface forming a slope in an area extending in the range of greater than or equal to 1 μm and less than or equal to 10 μm, for example; thus, such an organic film has a shape whose top surface and side surface are difficult to distinguish from each other.

An insulating layer 225, a resin layer 226, and a layer 228 are included between two adjacent light-emitting elements.

Between two adjacent light-emitting elements, the side surfaces of the organic layers 212 are provided to face each other with the resin layer 226 therebetween. The resin layer 226 is positioned between the two adjacent light-emitting elements and is provided to fill regions between end portions of the organic layers 212 and between the two organic layers 212. The resin layer 226 has a top surface with a smooth convex shape, and the common layer 214 and the common electrode 213 are provided to cover the top surface of the resin layer 226.

The resin layer 226 functions as a planarization film that fills a gap positioned between two adjacent light-emitting elements. Providing the resin layer 226 can prevent a phenomenon in which the common electrode 213 is divided by a step at an end portion of the organic layer 212 (such a phenomenon is also referred to as disconnection) from occurring and the common electrode over the organic layer 212 from being insulated. The resin layer 226 can be also referred to as LFP (Local Filling Planarization).

An insulating layer containing an organic material can be suitably used as the resin layer 226. For the resin layer 226, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 226, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 226. A photoresist may be used for the photosensitive resin. As the photosensitive resin, a positive photosensitive material or a negative photosensitive material can be used.

The resin layer 226 may contain a material absorbing visible light. For example, the resin layer 226 itself may be made of a material absorbing visible light, or the resin layer 226 may contain a pigment absorbing visible light. For example, for the resin layer 226, it is possible to use a resin that can be used as a color filter transmitting red, blue, or green light and absorbing other light, a resin that contains carbon black as a pigment and functions as a black matrix, or the like.

The insulating layer 225 is provided in contact with the side surface of the organic layers 212. In addition, the insulating layer 225 is provided to cover an upper end portion of the organic layer 212. Furthermore, part of the insulating layer 225 is provided in contact with the top surface of the layer 201.

The insulating layer 225 is positioned between the resin layer 226 and the organic layer 212 and functions as a protective film for preventing contact between the resin layer 226 and the organic layer 212. When the organic layer 212 and the resin layer 226 are in contact with each other, the organic layer 212 might be dissolved in an organic solvent or the like used at the time of forming the resin layer 226. Therefore, the insulating layer 225 is provided between the organic layer 212 and the resin layer 226 to protect the side surfaces of the organic layer 212.

An insulating layer containing an inorganic material can be used for the insulating layer 225. For the insulating layer 225, an inorganic insulating film such as an oxide insulating film, a nitride insulating film, an oxynitride insulating film, or a nitride oxide insulating film can be used, for example. The insulating layer 225 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 225, it is possible to form the insulating layer 225 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 225, a sputtering method, a CVD method, a PLD method, an ALD method, or the like can be used. The insulating layer 225 is preferably formed by an ALD method that provides good coverage.

A structure may be employed in which a reflective film (e.g., a metal film containing one or more selected from silver, palladium, copper, titanium, aluminum, and the like) is provided between the insulating layer 225 and the resin layer 226 so that light emitted from the light-emitting layer is reflected by the reflective film. This can improve light extraction efficiency.

The layer 228 is a remaining part of a protective layer (also referred to as a mask layer or a sacrificial layer) for protecting the organic layer 212 during etching of the organic layer 212. For the layer 228, a material that can be used for the insulating layer 225 can be used. It is particularly preferable to use the same material for the layer 228 and the insulating layer 225 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 225 and the layer 228.

The protective layer 221 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 221.

For the protective layer 221, a stacked film of an inorganic insulating film and an organic insulating film can be used. For example, a structure where an organic insulating film is interposed between a pair of inorganic insulating films is preferable. Furthermore, the organic insulating film preferably functions as a planarization film. This enables the top surface of the organic insulating film to be flat, which results in improved coverage with the inorganic insulating film thereover and a higher barrier property. The flat top surface of the protective layer 221 is preferable because when a component (e.g., a color filter, an electrode of a touch sensor, a lens array, or the like) is provided above the protective layer 221, the component can be less affected by an uneven shape caused by a lower structure.

FIG. 8C illustrates the connection portion 230 in which the connection electrode 211C and the common electrode 213 are electrically connected to each other. In the connection portion 230, an opening portion is provided in the insulating layer 225 and the resin layer 226 over the connection electrode 211C. The connection electrode 211C and the common electrode 213 are electrically connected to each other in the opening portion.

Note that although FIG. 8C illustrates the connection portion 230 in which the connection electrode 211C and the common electrode 213 are electrically connected to each other, the common electrode 213 may be provided over the connection electrode 211C with the common layer 214 therebetween. Particularly in the case where a carrier-injection layer is used as the common layer 214, for example, a material used for the common layer 214 has sufficiently low electrical resistivity and the common layer 214 can be formed to be thin; thus, problems do not arise in many cases even when the common layer 214 is positioned in the connection portion 230. Accordingly, the common electrode 213 and the common layer 214 can be formed using the same shielding mask, so that manufacturing cost can be reduced.

### Structure Example 2

A display panel whose structure is partly different from that of Structure example 1 is described below. Note that the above description can be referred to for portions common to those in Structure example 1, and the description is omitted in some cases.

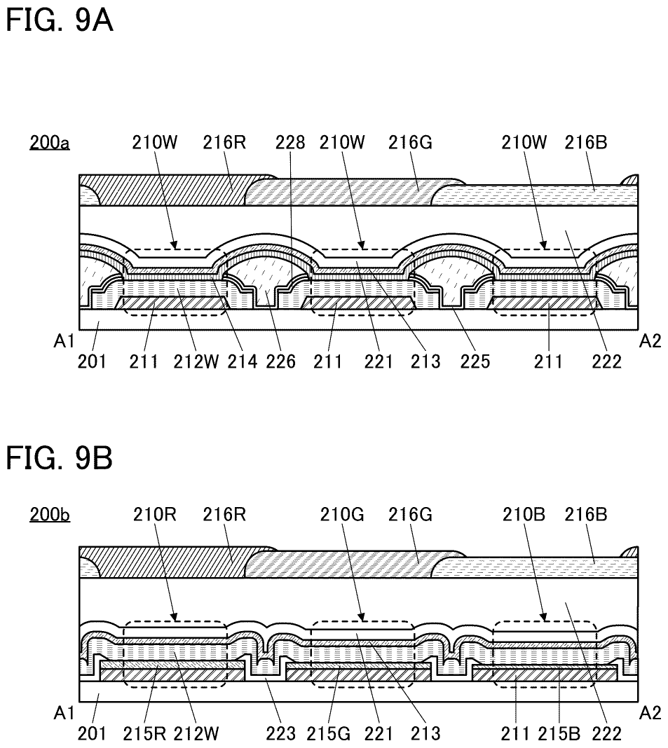

FIG. 9A is a schematic cross-sectional view of a display panel 200a. The display panel 200a is different from the display panel 200 mainly in the structure of the light-emitting element and including a coloring layer.

The display panel 200a includes light-emitting elements 210W that emit white light. The light-emitting elements 210W each include the pixel electrode 211, an organic layer 212W, the common layer 214, and the common electrode 213. The organic layer 212W emits white light. For example, the organic layer 212W can have a structure including two or more kinds of light-emitting materials whose emission colors are complementary colors. For example, the organic layer 212W can have a structure including a light-emitting organic compound that emits red light, a light-emitting organic compound that emits green light, and a light-emitting organic compound that emits blue light. Alternatively, the organic layer 212W may have a structure including a light-emitting organic compound that emits blue light and a light-emitting organic compound that emits yellow light.

The organic layer 212W is divided between two adjacent light-emitting elements 210W. Thus, leakage current flowing between the adjacent light-emitting elements 210W through the organic layer 212W can be inhibited and crosstalk due to the leakage current can be inhibited. Accordingly, the display panel can achieve high contrast and high color reproducibility.

An insulating layer 222 that functions as a planarization film is provided over the protective layer 221, and a coloring layer 216R, a coloring layer 216G, and a coloring layer 216B are provided over the insulating layer 222.

An organic resin film or an inorganic insulating film with a flat top surface can be used for the insulating layer 222. The coloring layer 216R, the coloring layer 216G, and the coloring layer 216B are formed on the insulating layer 222; thus, with the flat top surface of the insulating layer 222, the coloring layer 216R and the like can each have a uniform thickness to increase the color purity of light extracted from each light-emitting element. Note that when the thickness of the coloring layer 216R or the like is non-uniform, the amount of light absorption varies depending on a place in the coloring layer 216R, which might decrease the color purity.

### Structure Example 3

FIG. 9B is a schematic cross-sectional view of a display panel 200b.

The light-emitting element 210R includes the pixel electrode 211, a conductive layer 215R, the organic layer 212W, and the common electrode 213. The light-emitting element 210G includes the pixel electrode 211, a conductive layer 215G, the organic layer 212W, and the common electrode 213. The light-emitting element 210B includes the pixel electrode 211, a conductive layer 215B, the organic layer 212W, and the common electrode 213. The conductive layer 215R, the conductive layer 215G, and the conductive layer 215B each have a light-transmitting property and function as an optical adjustment layer.

A film reflecting visible light is used for the pixel electrode 211 and a film having a property of reflecting and transmitting visible light is used for the common electrode 213, so that a micro resonator (microcavity) structure can be achieved. In that case, by adjusting the thicknesses of the conductive layer 215R, the conductive layer 215G, and the conductive layer 215B to obtain optimal optical path length, light with different wavelengths and increased intensities can be obtained from the light-emitting element 210R, the light-emitting element 210G, and the light-emitting element 210B even when the organic layer 212 that emits white light is used.

Furthermore, the coloring layer 216R, the coloring layer 216G, and the coloring layer 216B are provided on the optical paths of the light-emitting element 210R, the light-emitting element 210G, and the light-emitting element 210B, respectively, so that light with high color purity can be obtained.

In addition, an insulating layer 223 that covers an end portion of the pixel electrode 211 and an end portion of an optical adjustment layer is provided. An end portion of the insulating layer 223 preferably has a tapered shape. When the insulating layer 223 is provided, coverage with the organic layer 212W, the common electrode 213, the protective layer 221, and the like provided over the insulating layer 223 can be increased.

The organic layer 212W and the common electrode 213 are each provided as one continuous film shared by the light-emitting elements. Such a structure is preferable because the manufacturing process of the display panel can be greatly simplified.

Here, the end portion of the pixel electrode 211 preferably has a shape substantially perpendicular to the top surface of the layer 201. Accordingly, a steep portion can be formed on the surface of the insulating layer 223, and thus a thin portion can be formed in part of the organic layer 212W that covers the steep portion or part of the organic layer 212W can be divided. Accordingly, leakage current generated between adjacent light-emitting elements through the organic layer 212W can be inhibited without processing the organic layer 212W by a photolithography method or the like.

The above is the description of the structure examples of the display panel.

### [Pixel Layout]

A pixel layout different from that in FIG. 8A will be mainly described below. There is no particular limitation on the arrangement of light-emitting elements (subpixels), and a variety of methods can be employed.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to a top surface shape of a light-emitting region of the light-emitting element.

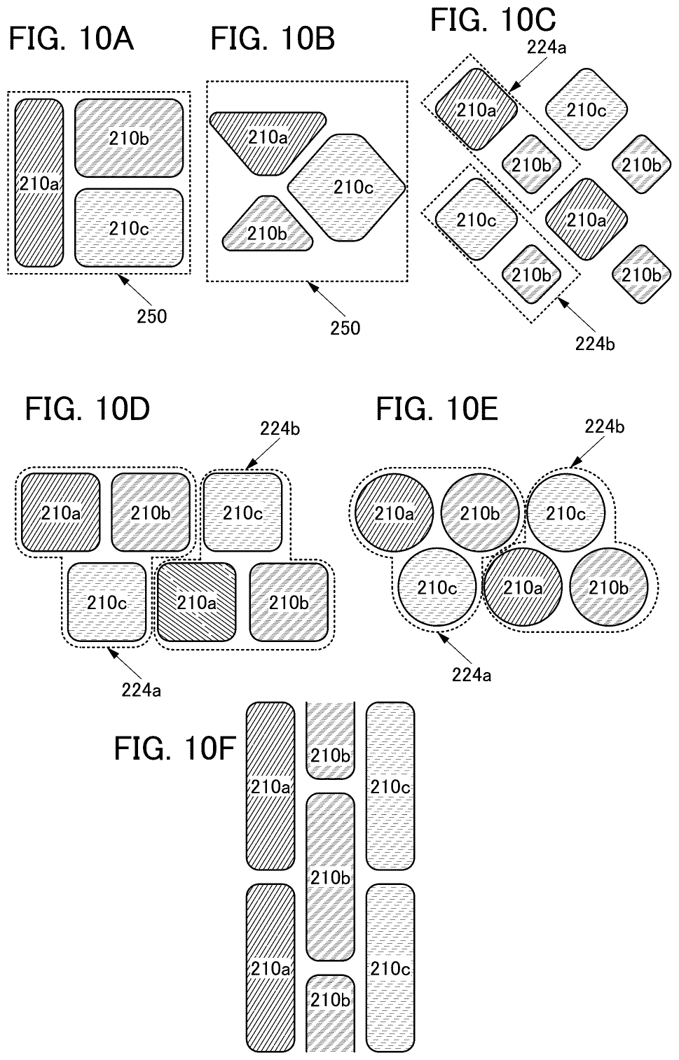

A pixel 250 illustrated in FIG. 10A employs S-stripe arrangement. The pixel 250 illustrated in FIG. 10A is composed of three subpixels: light-emitting elements 210a, 210b, and 210c. For example, the light-emitting element 210a may be a blue-light-emitting element, the light-emitting element 210b may be a red-light-emitting element, and the light-emitting element 210c may be a green-light-emitting element.

The pixel 250 illustrated in FIG. 10B includes the light-emitting element 210a whose top surface has a rough trapezoidal or rough triangle shape with rounded corners, the light-emitting element 210b whose top surface has a rough trapezoidal or rough triangle shape with rounded corners, and the light-emitting element 210c whose top surface has a rough tetragonal or rough hexagonal shape with rounded corners. The light-emitting element 210a has a larger light-emitting area than the light-emitting element 210b. In this manner, the shapes and sizes of the light-emitting elements can be independently determined. For example, the size of a light-emitting element with higher reliability can be made smaller. For example, the light-emitting element 210a may be a green-light-emitting element, the light-emitting element 210b may be a red-light-emitting element, and the light-emitting element 210c may be a blue-light-emitting element.

Pixels 224a and 224b illustrated in FIG. 10C employ PenTile arrangement. FIG. 10C illustrates an example in which the pixels 224a each including the light-emitting element 210a and the light-emitting element 210b and the pixels 224b each including the light-emitting element 210b and the light-emitting element 210c are alternately arranged. For example, the light-emitting element 210a may be a red-light-emitting element, the light-emitting element 210b may be a green-light-emitting element, and the light-emitting element 210c may be a blue-light-emitting element.

The pixels 224a and 224b illustrated in FIG. 10D and FIG. 10E employ delta arrangement. The pixel 224a includes two light-emitting elements (the light-emitting elements 210a and 210B) in an upper row (a first row) and one light-emitting element (the light-emitting element 210c) in a lower row (a second row). The pixel 224b includes one light-emitting element (the light-emitting element 210c) in the upper row (the first row) and two light-emitting elements (the light-emitting elements 210a and 210b) in the lower row (the second row). For example, the light-emitting element 210a may be a red-light-emitting element, the light-emitting element 210b may be a green-light-emitting element, and the light-emitting element 210c may be a blue-light-emitting element.

FIG. 10D illustrates an example in which the top surface of each light-emitting element has a rough tetragonal shape with rounded corners, and FIG. 10E illustrates an example in which the top surface of each light-emitting element has a circular shape.

FIG. 10F illustrates an example in which light-emitting elements of different colors are arranged in a zigzag manner. Specifically, the positions of top sides of two light-emitting elements arranged in a column direction (e.g., the light-emitting element 210a and the light-emitting element 210B or the light-emitting element 210b and the light-emitting element 210c) are not aligned in a top view. For example, the light-emitting element 210a may be a red-light-emitting element, the light-emitting element 210b may be a green-light-emitting element, and the light-emitting element 210c may be a blue-light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel of one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, the top surface of the EL layer has a polygonal shape with rounded corners, an elliptical shape, a circular shape, or the like in some cases. For example, when a resist mask with a square top surface is intended to be formed, a resist mask with a circular top surface might be formed, and the top surface of the EL layer might have a circular shape.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in combination with the other embodiments described in this specification as appropriate.

### Embodiment 4

In this embodiment, other structure examples of a display panel that can be employed for the electronic device of one embodiment of the present invention will be described.

Display panels in this embodiment are high-resolution display panels, and particularly suitably used for display portions of wearable devices that can be worn on a head, such as VR devices like head-mounted displays and glasses-type AR devices. The structure of the display device 10 shown in Embodiment 1 can be used for the display panels in this embodiment.

### [Display Module]

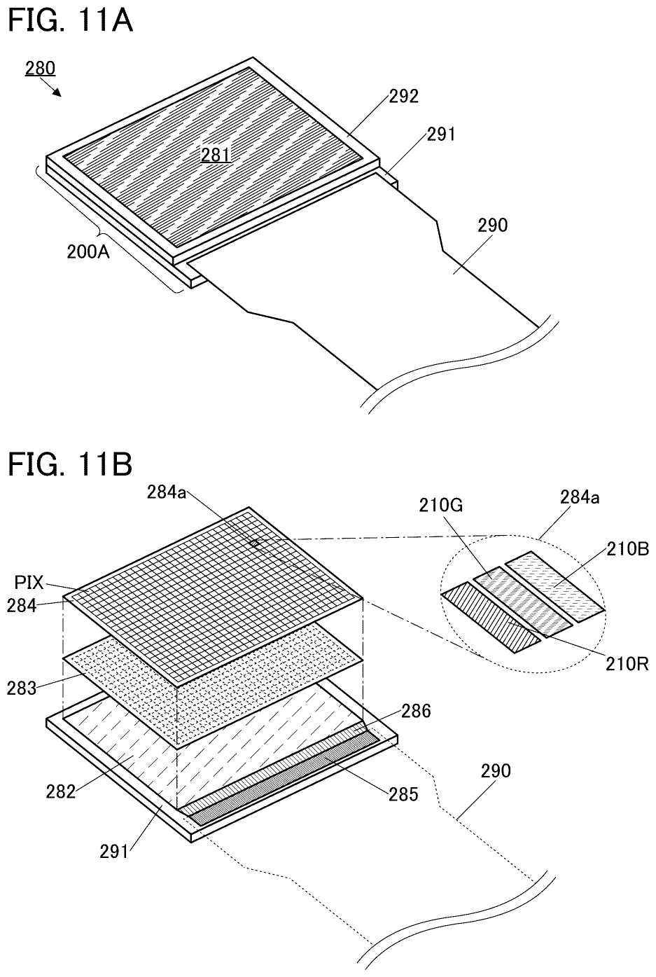

FIG. 11A is a perspective view of a display module 280. The display module 280 includes a display panel 200A and an FPC 290. The structure of the display device 10 shown in Embodiment 1 can be used for the display panel 200A.

The display module 280 includes a substrate 291, a substrate 292, and a display portion 281. The display portion 281 is a region where an image is displayed. The substrate 291 corresponds to the layer 20 shown in Embodiment 1, and the layer 30 including a light-emitting element and the like are provided between the substrate 291 and the substrate 292. As the substrate 292, a glass substrate having high transmittance of light emitted from the light-emitting element can be used, for example.

FIG. 11B is a perspective view schematically illustrating the structure on the substrate 291 side. Over the substrate 291, a circuit portion 282, a circuit portion 283 over the circuit portion 282, and a circuit portion 284 over the circuit portion 283 are stacked. Here, the circuit 21a shown in Embodiment 1 is provided in the circuit portion 282. The circuit 21b shown in Embodiment 1 is provided in the circuit portion 283. The pixel circuit PIX shown in Embodiment 1 is provided in the circuit portion 284.

A terminal portion 285 to be connected to the FPC 290 is provided over the substrate 291. The terminal portion 285 and the circuit portion 282 are electrically connected to each other through a wiring portion 286 formed of a plurality of wirings.

The circuit portion 284 includes a plurality of pixels 284a arranged periodically. An enlarged view of one pixel 284a is illustrated on the right side in FIG. 11B. The pixel 284a includes the light-emitting element 210R that emits red light, the light-emitting element 210G that emits green light, and the light-emitting element 210B that emits blue light.

The circuit portion 284 includes a plurality of pixel circuits PIX arranged periodically. One pixel circuit PIX is a circuit for controlling light emission of three light-emitting devices included in one pixel 284a. One pixel circuit PIX may be provided with three circuits for controlling light emission of one light-emitting device. For example, the pixel circuit PIX can include at least one selection transistor, one current control transistor (driving transistor), and a capacitor element for one light-emitting device. In that case, a gate signal is input to a gate of the selection transistor, and a source signal is input to a source of the selection transistor. Thus, an active-matrix display panel is achieved.

The circuit portion 282 and the circuit portion 283 each include a circuit for driving the pixel circuits PIX. The FPC 290 functions as a wiring for supplying video data, a power supply potential, and the like to the circuit portion 282 from the outside. In addition, an IC may be mounted on the FPC 290.

The display module 280 can have a structure in which both of the circuit portion 283 and the circuit portion 282 are stacked below the circuit portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as a head-mounted display or a glasses-type AR device. For example, even in the case of a structure where the display portion of the display module 280 is seen through a lens, pixels of the extremely-high-resolution display portion 281 included in the display module 280 are not seen even when the display portion is enlarged by the lens, so that display providing a high sense of immersion can be performed. Without being limited thereto, the display module 280 can be also suitably used for an electronic device having a relatively small display portion. For example, the display module 280 can be suitably used for a display portion of a wearable electronic device such as a wristwatch.

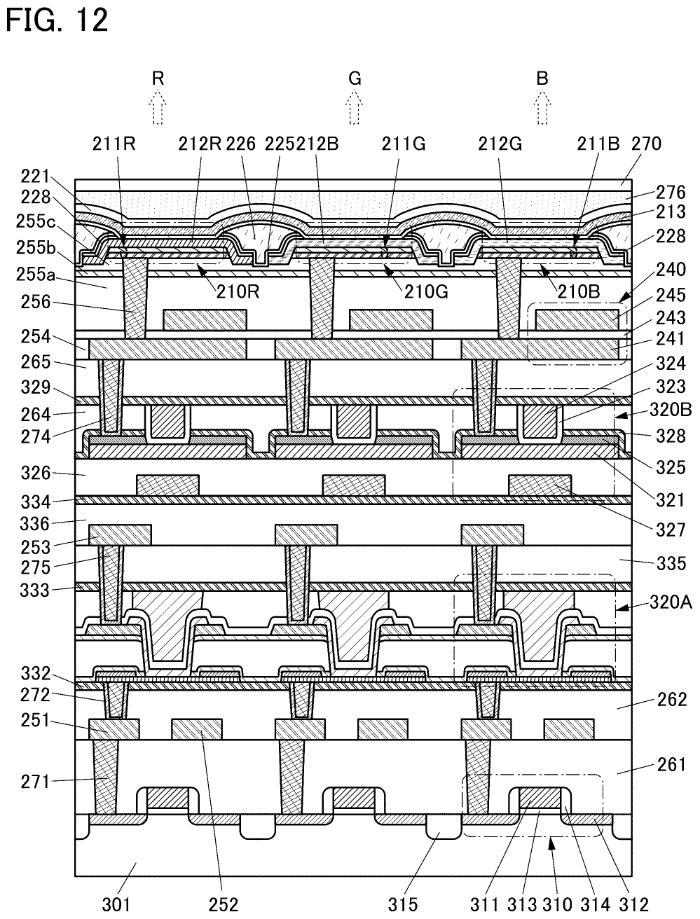

The display panel 200A illustrated in FIG. 12 has a structure in which a transistor 310 whose channel is formed in a substrate 301, and a transistor 320A and a transistor 320B each including a metal oxide in a semiconductor layer where a channel is formed are stacked. Note that the stacked-layer structure illustrated in FIG. 12 is an example of the structure illustrated in FIG. 2A.

Here, the substrate 301 corresponds to the substrate 291 in FIG. 11A and FIG. 11B. The transistor 310, the transistor 320A, and the transistor 320B respectively correspond to the Si transistor provided in the layer 20, the first OS transistor provided in the layer 30a, and the second OS transistor provided in the layer 30b, which are described in Embodiment 1.

The transistor 310 and the transistor 320A can each be used as a transistor included in a driver circuit (a gate driver or a source driver) for driving a pixel circuit or a transistor included in a functional circuit. The transistor 320B can be used as a transistor included in the pixel circuit.

The transistor 310 is a transistor that includes a channel formation region in the substrate 301. As the substrate 301, a semiconductor substrate such as a single crystal silicon substrate can be used, for example. Although a planar transistor is illustrated as an example as the transistor 310 in FIG. 12, a fin-type transistor may be used.

The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 310 so as to be embedded in the substrate 301.

An insulating layer 261 is provided to cover the transistors 310, and a conductive layer 251 and a conductive layer 252 are provided over the insulating layer 261. An insulating layer 262 is provided to cover the conductive layers 251 and 252. The conductive layers 251 and 252 function as wirings. An insulating layer 332 is provided over the insulating layer 262, and the transistor 320A is provided over the insulating layer 332.

The insulating layer 332 functions as a barrier layer that prevents diffusion of impurities such as water or hydrogen from the substrate 301 side into the transistor 320A. As the insulating layer 332, for example, a film in which hydrogen or oxygen is less likely to diffuse than in a silicon oxide film, such as an aluminum oxide film, a hafnium oxide film, or a silicon nitride film, can be used.

The transistor 320A is a vertical transistor, and the description of the first OS transistor described in Embodiment 1 can be referred to for the details.

The transistor 320A is electrically connected to the transistor 310 through a plug 272, the conductive layer 251, and a plug 271. An insulating layer 333, an insulating layer 335, an insulating layer 336, a plug 275 electrically connected to the transistor 320A, a conductive layer 253 electrically connected to the plug 275, and the like can be provided over the transistor 320A as appropriate.

An insulating layer 334 is provided over the transistor 320A, and the transistor 320B is provided over the insulating layer 334. As the insulating layer 334, an insulating film similar to the insulating layer 332 can be used.

The transistor 320B is a transistor including a metal oxide (also referred to as an oxide semiconductor) in a semiconductor layer where a channel is formed and corresponds to the second OS transistor shown in Embodiment 1. The transistor 320B corresponds to the transistor M2 or the transistor M6 that is a driving transistor in the pixel circuit illustrated in FIG. 6A or FIG. 6B.

The transistor 320B includes a semiconductor layer 321, an insulating layer 323, a conductive layer 324, a pair of conductive layers 325, an insulating layer 326, and a conductive layer 327.

The conductive layer 327 is provided over the insulating layer 334, and the insulating layer 326 is provided to cover the conductive layer 327. The conductive layer 327 functions as a first gate electrode of the transistor 320B, and part of the insulating layer 326 functions as a first gate insulating layer. An oxide insulating film such as a silicon oxide film is preferably used for at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided over and in contact with the semiconductor layer 321, and functions as a source electrode and a drain electrode.

An insulating layer 328 is provided to cover top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with a top surface of the semiconductor layer 321 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are subjected to planarization treatment so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320B. For the insulating layer 329, an insulating film similar to the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a first conductive layer that covers side surfaces of openings in the insulating layer 265, the insulating layer 329, the insulating layer 264, and the insulating layer 328 and part of a top surface of the conductive layer 325, and a second conductive layer in contact with a top surface of the first conductive layer. In that case, a conductive material in which hydrogen and oxygen are less likely to diffuse is preferably used for the first conductive layer.

Note that the transistor 320B can be any of a planar transistor, a staggered transistor, an inverted staggered transistor, a trench-type transistor, a fin-type transistor, and the like. In addition, the transistor structure may be either a top-gate structure or a bottom-gate structure.

A structure in which the semiconductor layer where a channel is formed is interposed between two gates is employed for the transistor 320B. The two gates may be connected to each other and supplied with the same signal to drive the transistor. Alternatively, a potential for controlling the threshold voltage may be supplied to one of the two gates and a potential for driving may be supplied to the other of the two gates to control the threshold voltage of the transistor.

There is no particular limitation on the crystallinity of a semiconductor material used for the semiconductor layer of the transistor 320B, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The bandgap of a metal oxide used for the semiconductor layer of the transistor 320B is preferably greater than or equal to 2 eV, further preferably greater than or equal to 2.5 eV. The use of a metal oxide having a wide bandgap can reduce the off-state current of the OS transistor. Note that for the transistor 320B (the second OS transistor), a metal oxide similar to the metal oxide that can be used for the first OS transistor described in Embodiment 2 can be used.

An OS transistor has extremely higher field-effect mobility than a transistor using amorphous silicon. In addition, the OS transistor has an extremely low leakage current between a source and a drain in an off state (hereinafter also referred to as off-state current), and charge accumulated in a capacitor that is connected in series with the transistor can be retained for a long period. Furthermore, the power consumption of the display panel can be reduced with the use of the OS transistor.

In order to increase the emission luminance of the light-emitting device included in the pixel circuit, the amount of current flowing through the light-emitting device needs to be increased. To increase the current amount, the source-drain voltage of a driving transistor included in the pixel circuit needs to be increased. Since the OS transistor has higher withstand voltage between the source and the drain than a Si transistor, high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current relative to a change in gate-source voltage is smaller in an OS transistor than in a Si transistor. Accordingly, when an OS transistor is used as the driving transistor included in the pixel circuit, the amount of current flowing between the source and the drain can be finely set by a change in gate-source voltage; thus, the amount of current flowing through the light-emitting device can be controlled. Therefore, the number of gray levels in the pixel circuit can be increased.

Regarding the saturation characteristics of current flowing when a transistor operates in a saturation region, even in the case where the source-drain voltage of an OS transistor gradually increases, more stable current (saturation current) can be fed through the OS transistor than through a Si transistor. Thus, by using an OS transistor as the driving transistor, stable current can be fed through the light-emitting device even when the current-voltage characteristics of EL devices vary, for example. In other words, when the OS transistor operates in the saturation region, the source-drain current hardly changes even with an increase in the source-drain voltage; thus, the emission luminance of the light-emitting device can be stable.

As described above, with the use of an OS transistor as the driving transistor included in the pixel circuit, it is possible to achieve “reduction in power consumption”, “increase in emission luminance”, “increase in the number of gray levels”, “inhibition of variation in light-emitting devices,” and the like.

The insulating layer 265 is provided over the insulating layer 329, and a capacitor 240 is provided over the insulating layer 265. The capacitor 240 and the transistor 320B are electrically connected to each other through the plug 274. The capacitor 240 corresponds to the transistor capacitor element C1 or the capacitor element C2 illustrated in FIG. 6A to FIG. 6D.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 265 and is embedded in an insulating layer 254. The conductive layer 241 is electrically connected to one of a source and a drain of the transistor 320B through a plug 256 embedded in an insulating layer 255a. The insulating layer 243 is provided to cover the conductive layer 241. The conductive layer 245 is provided in a region overlapping with the conductive layer 241 with the insulating layer 243 therebetween.

The insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and a silicon nitride film be used for the insulating layer 255b. This enables the insulating layer 255b to function as an etching protective film. Although this embodiment shows an example in which the insulating layer 255c is partly etched to form a depressed portion, the depressed portion is not necessarily provided in the insulating layer 255c.

The light-emitting element 210R, the light-emitting element 210G, and the light-emitting element 210B are provided over the insulating layer 255c. Embodiment 3 can be referred to for the structures of the light-emitting element 210R, the light-emitting element 210G, and the light-emitting element 210B.

Since the light-emitting devices for different emission colors are separately formed in the display panel 200A, the difference between the chromaticity at low luminance emission and that at high luminance emission is small. Furthermore, since the organic layers 212R, 212G, and 212B are apart from each other, crosstalk generated between adjacent subpixels can be inhibited even when the display panel has a high resolution. It is thus possible to achieve a display panel that has a high resolution and high display quality.

In a region between adjacent light-emitting elements, the insulating layer 225, the resin layer 226, and the layer 228 are provided.

The pixel electrode 211R, the pixel electrode 211G, and the pixel electrode 211B of the light-emitting elements are each electrically connected to one of the source and the drain of the transistor 320B through the plug 256 that is embedded in the insulating layer 255a, the insulating layer 255b, and the insulating layer 255c, the conductive layer 241 that is embedded in the insulating layer 254, and the plug 274 that is embedded in the insulating layer 265. A top surface of the insulating layer 255c and a top surface of the plug 256 are level with or substantially level with each other. A variety of conductive materials can be used for the plugs.

The protective layer 221 is provided over the light-emitting elements 210R, 210G, and 210B. A substrate 270 is attached onto the protective layer 221 with an adhesive layer 276. The substrate 270 corresponds to the substrate 292 in FIG. 11A.

An insulating layer covering an end portion of a top surface of the pixel electrode 211 is not provided between two adjacent pixel electrodes 211. Thus, the distance between adjacent light-emitting elements can be extremely shortened. Accordingly, the display panel can have a high resolution or a high definition.

Note that in the structure described above, the first OS transistor is formed over the Si transistor with an insulating layer therebetween and the transistors are electrically connected to each other through a plug; alternatively, electrical connection between the Si transistor and the first OS transistor may be performed by bonding.

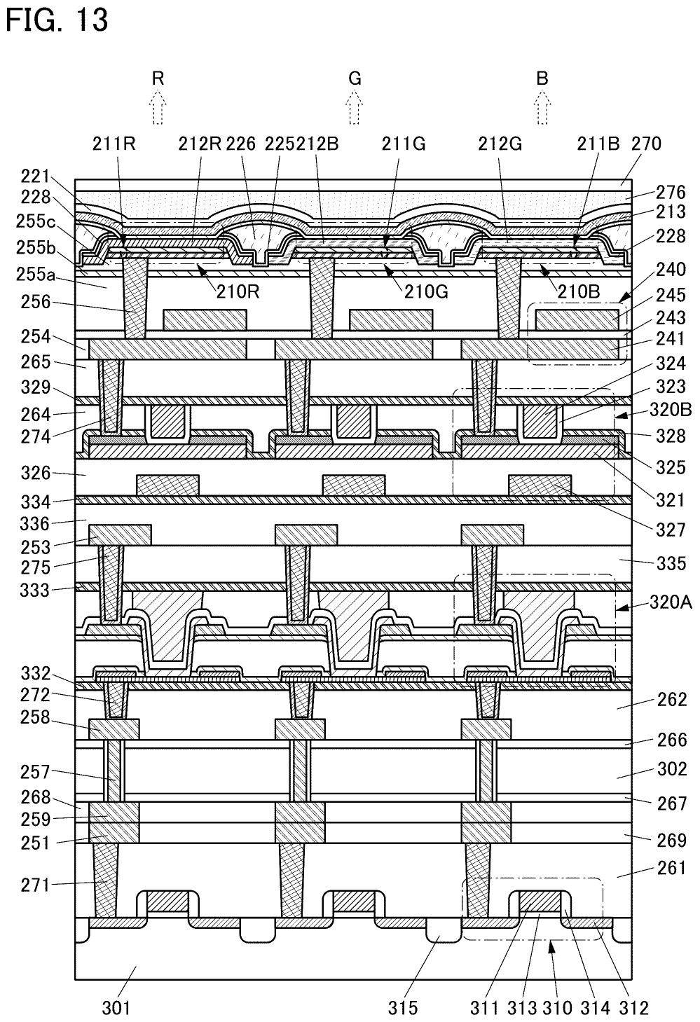

FIG. 13 illustrates a structure in which the transistor 310 (the Si transistor) formed on the substrate 301 and the transistor 320A (the first OS transistor) are electrically connected to each other by bonding. Note that the description of the structure of the layer above the transistor 320A is omitted.

The transistor 320A is formed using a silicon substrate 302 as a support substrate. An insulating layer 266 is formed over a first surface of the silicon substrate 302, and a conductive layer 258 is provided over the insulating layer 266. One of a source and a drain of the transistor 320A is electrically connected to the conductive layer 258 through the insulating layer 262 provided over the insulating layer 266 and the conductive layer 258 and the plug 272 embedded in the insulating layer 332.

An insulating layer 267 is formed over a second surface opposite to the first surface of the silicon substrate 302, and an insulating layer 268 and a conductive layer 259 are provided over the insulating layer 267. Here, the insulating layer 268 and the conductive layer 259 also function as bonding layers, the conductive layer 259 includes a region embedded in the insulating layer 268, and top surfaces of the insulating layer 268 and the conductive layer 259 are planarized.

A through hole is formed in the silicon substrate 302, and the conductive layer 258 and the conductive layer 259 are electrically connected to each other through a through electrode 257 formed in the through hole with an insulating layer therebetween.

The insulating layer 261 is provided over the transistor 310 provided over the substrate 301, and an insulating layer 269 and the conductive layer 251 are provided over the insulating layer 261. Here, the insulating layer 269 and the conductive layer 251 also function as bonding layers, the conductive layer 251 includes a region embedded in the insulating layer 269, and top surfaces of the insulating layer 269 and the conductive layer 251 are planarized.

The surfaces of the insulating layer 268 and the insulating layer 269 are in contact with each other and the surfaces of the conductive layer 259 and the conductive layer 251 are in contact with each other to be bonded to each other. Thus, the transistor 310 and the transistor 320A can be electrically connected to each other by bonding.

Note that the insulating layer 268 and the insulating layer 269 are preferably inorganic insulating layers formed using the same material. The same conductive material is preferably used for the conductive layer 259 and the conductive layer 251. A metal film containing an element selected from Al, Cr, Cu, Ta, Ti, Mo, and W, a metal nitride film containing the above element as a component (a titanium nitride film, a molybdenum nitride film, or a tungsten nitride film), or the like can be used, for example. Copper is particularly preferably used for the conductive layer 259 and the conductive layer 251 for easy bonding.

Although an example in which the transistor 320A is used as a transistor included in the driver circuit or the functional circuit is described above, the transistor 320A can also be used as a transistor included in the pixel circuit.

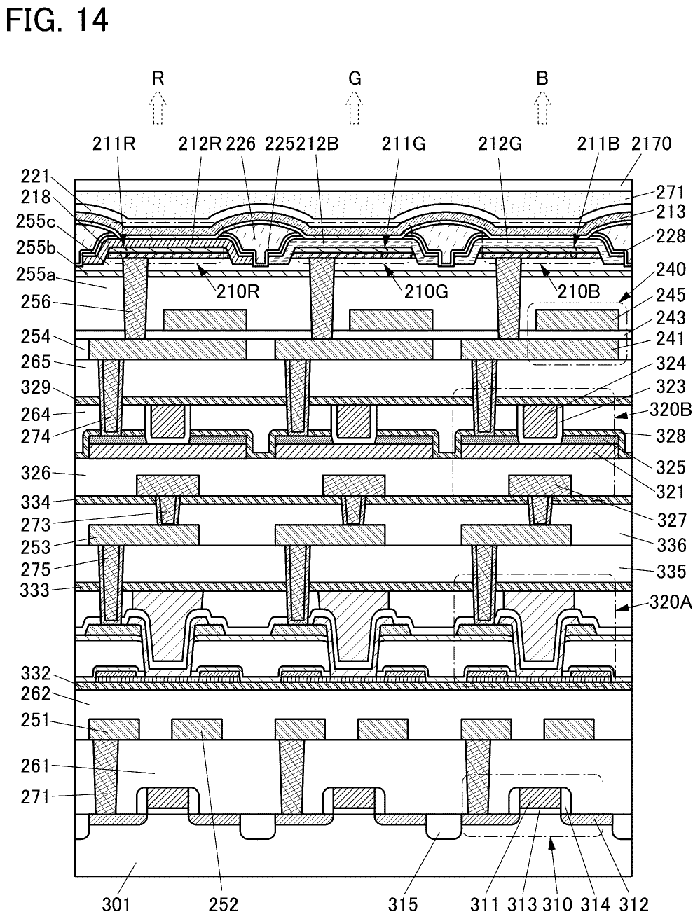

FIG. 14 illustrates an example in which the transistor 320A is used as a selection transistor in the pixel circuit. The selection transistor in the pixel circuit is preferably capable of high-speed driving; thus, a vertical transistor with a high on-state current may be used. Meanwhile, since the driving transistor preferably has favorable saturation characteristics, a transistor with a relatively long channel length is preferably used; hence, the driving transistor is preferably formed with a transistor whose channel length can be determined by a lithography process.

Here, when the transistor 320B has a structure in which the front gate and the back gate are electrically connected to each other as the transistor M2 (the driving transistor) illustrated in FIG. 6B, one of the source and the drain of the transistor 320A is electrically connected to the conductive layer 327, which is the back gate of the transistor 320B.

That is, the gate of the transistor 320B can be electrically connected to one of the source and the drain of the transistor 320A with a simpler structure than the structure in which the gate of the transistor 320A includes only the conductive layer 324 (without a back gate).

Note that FIG. 14 illustrates the structure in which the transistor 320A and the transistor 320B are electrically connected to each other through the plug 275, the conductive layer 253, and a plug 273; alternatively, the transistor 320A and the transistor 320B may be electrically connected to each other through only one of the plug 275 and the plug 273.

Although FIG. 14 does not illustrate the transistor 320A as a component of the driver circuit, the transistor 320A can be used as components of both a pixel circuit and a driver circuit with the structure illustrated in FIG. 2B or FIG. 2C.

At least part of this embodiment can be implemented in combination with the other embodiments described in this specification as appropriate.

### Embodiment 5

In this embodiment, a light-emitting device (a light-emitting element) that can be used in the display panel of one embodiment of the present invention will be described.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM is sometimes referred to as a device having an MML (metal maskless) structure.

In this specification and the like, a structure where at least light-emitting layers of light-emitting devices having different emission wavelengths are separately formed is sometimes referred to as an SBS (Side By Side) structure. The SBS structure can optimize materials and structures of the light-emitting devices and thus can increase the degree of freedom in selecting the materials and the structures, which facilitates improvement in luminance and improvement in reliability.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. Furthermore, one layer has two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Here, examples of a layer included in the EL layer (also referred to as a functional layer) include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

As the light-emitting device, an OLED (Organic Light Emitting Diode) or a QLED (Quantum-dot Light Emitting Diode) is preferably used, for example. Examples of a light-emitting substance contained in the light-emitting device include a substance exhibiting fluorescence (a fluorescent material), a substance exhibiting phosphorescence (a phosphorescent material), a substance exhibiting thermally activated delayed fluorescence (a thermally activated delayed fluorescent (Thermally activated delayed fluorescence: TADF) material), and an inorganic compound (a quantum-dot material or the like). In addition, an LED such as a micro LED can be also used as the light-emitting device.

The emission color of the light-emitting device can be infrared, red, green, blue, cyan, magenta, yellow, white, or the like. Furthermore, color purity can be increased when the light-emitting device has a microcavity structure.

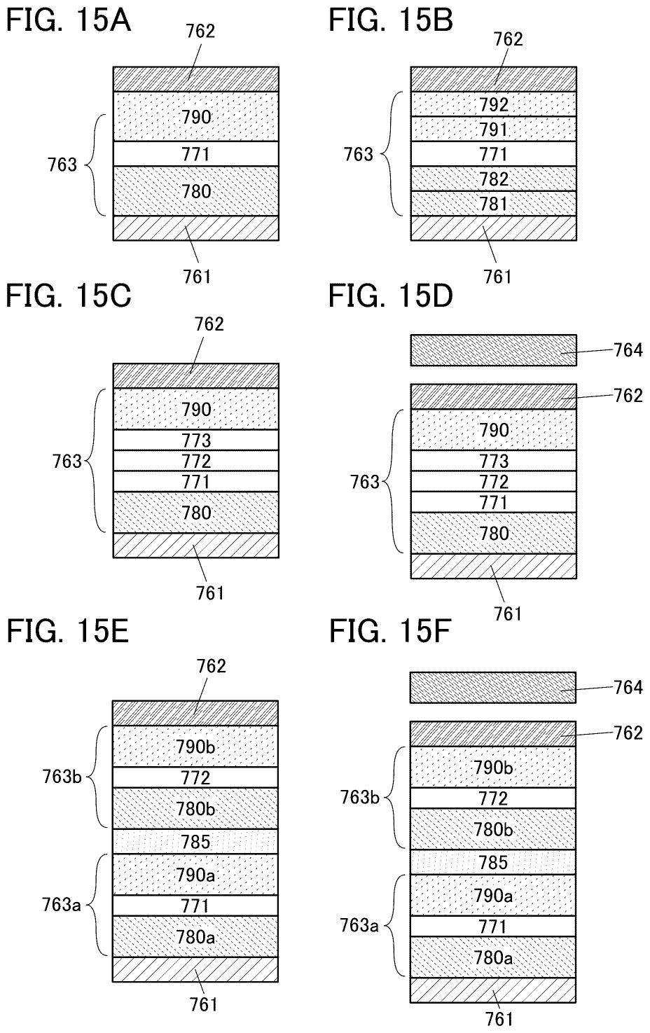

As illustrated in FIG. 15A, the light-emitting device includes an EL layer 763 between a pair of electrodes (a lower electrode 761 and an upper electrode 762). The EL layer 763 can be formed using a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790 that is provided between the pair of electrodes can function as a single light-emitting unit, and the structure in FIG. 15A is referred to as a single structure in this specification.

FIG. 15B is a modification example of the EL layer 763 included in the light-emitting device illustrated in FIG. 15A. Specifically, the light-emitting device illustrated in FIG. 15B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of recombination of carriers in the light-emitting layer 771 can be increased.

Note that structures where a plurality of light-emitting layers (light-emitting layers 771, 772, and 773) are provided between the layer 780 and the layer 790 as illustrated in FIG. 15C and FIG. 15D are other variations of the single structure. Note that although FIG. 15C and FIG. 15D each illustrate the example where three light-emitting layers are included, the light-emitting device having a single structure may include two light-emitting layers or four or more light-emitting layers. In addition, the light-emitting device having a single structure may include a buffer layer between two light-emitting layers.

A structure in which a plurality of light-emitting units (a light-emitting unit 763a and a light-emitting unit 763b) are connected in series with a charge-generation layer 785 (also referred to as an intermediate layer) therebetween as illustrated in FIG. 15E and FIG. 15F is referred to as a tandem structure in this specification. Note that the tandem structure may be referred to as a stack structure. The tandem structure enables a light-emitting device capable of light emission at high luminance. Furthermore, the tandem structure can reduce the amount of current needed for obtaining the same luminance as compared with the single structure, and thus can increase reliability.

Note that FIG. 15D and FIG. 15F each illustrate an example in which the display panel includes a layer 764 overlapping with the light-emitting device. FIG. 15D illustrates an example in which the layer 764 overlaps with the light-emitting device illustrated in FIG. 15C, and FIG. 15F illustrates an example in which the layer 764 overlaps with the light-emitting device illustrated in FIG. 15E.

One or both of a color conversion layer and a color filter (a coloring layer) can be used for the layer 764.

In FIG. 15C and FIG. 15D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 15D, so that blue light emitted from the light-emitting device can be converted into light with a longer wavelength and thus red light or green light can be extracted.

Light-emitting substances that emit light of different colors may be used for the light-emitting layer 771, the light-emitting layer 772, and the light-emitting layer 773. White light emission can be obtained when the emission colors of the light-emitting layer 771, the light-emitting layer 772, and the light-emitting layer 773 are complementary colors. The light-emitting device having a single structure preferably includes a light-emitting layer containing a light-emitting substance that emits blue light and a light-emitting layer containing a light-emitting substance that emits visible light with a longer wavelength than blue light, for example.

In the case where the light-emitting device having a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be R, G, and B from the anode side or R, B, and G from the anode side, for example. In that case, a buffer layer may be provided between R and G or between R and B.

In the case where the light-emitting device having a single structure includes two light-emitting layers, for example, a light-emitting layer containing a light-emitting substance that emits blue (B) light and a light-emitting layer containing a light-emitting substance that emits yellow light are preferably included. Such a structure is sometimes referred to as a BY single structure.

A color filter may be provided as the layer 764 illustrated in FIG. 15D. When white light passes through the color filter, light of a desired color can be obtained.

A light-emitting device that emits white light preferably contains two or more kinds of light-emitting substances. To obtain white light emission, two or more light-emitting substances are selected such that their emission colors are complementary colors. For example, when the emission color of a first light-emitting layer and the emission color of a second light-emitting layer are complementary colors, the light-emitting device can be configured to emit white light as a whole. The same applies to a light-emitting device including three or more light-emitting layers.

In FIG. 15E and FIG. 15F, light-emitting substances that emit light of the same color or the same light-emitting substance may be used for the light-emitting layer 771 and the light-emitting layer 772.

For example, in light-emitting devices included in subpixels that emit light of respective colors, a light-emitting substance that emits blue light may be used for each of the light-emitting layer 771 and the light-emitting layer 772. In a subpixel that emits blue light, blue light emitted from the light-emitting device can be extracted. In each of a subpixel that emits red light and a subpixel that emits green light, a color conversion layer is provided as the layer 764 illustrated in FIG. 15F, so that blue light emitted from the light-emitting device can be converted into light with a longer wavelength and thus red light or green light can be extracted.

Alternatively, in the case where the light-emitting device having the structure illustrated in FIG. 15E or FIG. 15F is used for the subpixels that emit light of respective colors, the subpixels may use different light-emitting substances. Specifically, in the light-emitting device included in the subpixel that emits red light, a light-emitting substance that emits red light may be used for each of the light-emitting layer 771 and the light-emitting layer 772. Similarly, in the light-emitting device included in the subpixel that emits green light, a light-emitting substance that emits green light may be used for each of the light-emitting layer 771 and the light-emitting layer 772. In the light-emitting device included in the subpixel that emits blue light, a light-emitting substance that emits blue light may be used for each of the light-emitting layer 771 and the light-emitting layer 772. A display panel having such a structure can be regarded as employing a light-emitting device with a tandem structure and an SBS structure. Thus, the display panel can have both the advantage of a tandem structure and the advantage of an SBS structure. Accordingly, a light-emitting device capable of light emission at high luminance and having high reliability can be achieved.

In FIG. 15E and FIG. 15F, light-emitting substances that emit light of different colors may be used for the light-emitting layer 771 and the light-emitting layer 772. White light emission can be obtained when light emitted from the light-emitting layer 771 and light emitted from the light-emitting layer 772 have complementary colors. A color filter may be provided as the layer 764 illustrated in FIG. 15F. When white light passes through the color filter, light of a desired color can be obtained.

Note that although FIG. 15E and FIG. 15F each illustrate an example in which the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 15E and FIG. 15F each illustrate the example of the light-emitting device including two light-emitting units, one embodiment of the present invention is not limited thereto. The light-emitting device may include three or more light-emitting units.

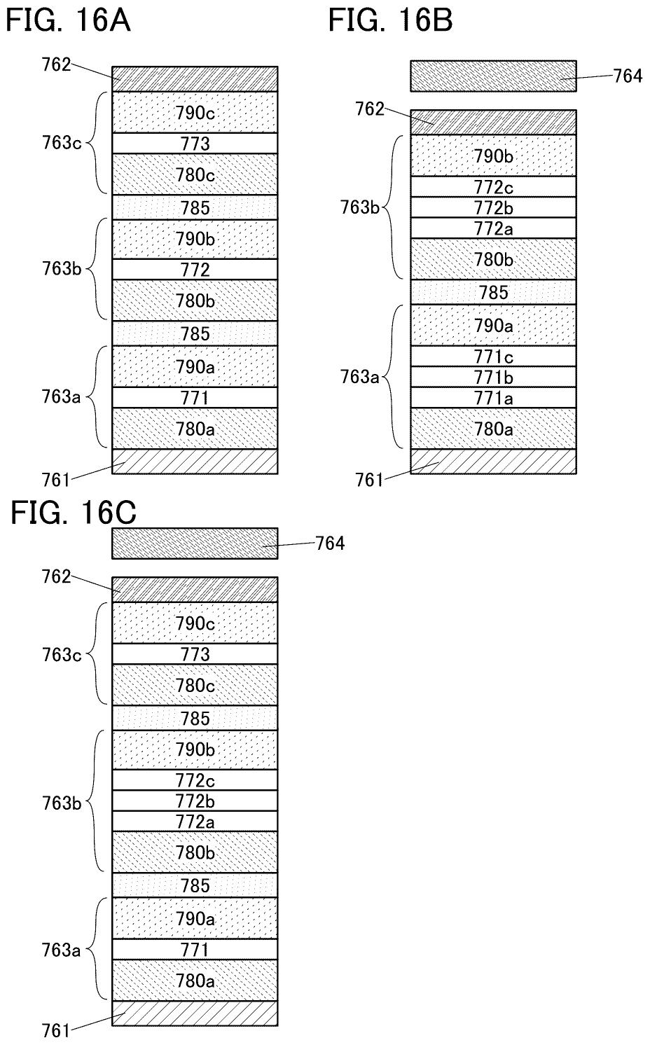

Specifically, structures of the light-emitting device illustrated in FIG. 16A to FIG. 16C can be given.

FIG. 16A illustrates a structure including three light-emitting units. Note that a structure including two light-emitting units and a structure including three light-emitting units may be referred to as a two-unit tandem structure and a three-unit tandem structure, respectively.

In the structure illustrated in FIG. 16A, a plurality of light-emitting units (the light-emitting unit 763a, the light-emitting unit 763b, and a light-emitting unit 763c) are connected in series with the charge-generation layers 785 therebetween. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

Note that in the structure illustrated in FIG. 16A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (what is called a three-unit R\R\R tandem structure), the light-emitting layer 771, the light-emitting layer 772, and the light-emitting layer 773 can each contain a light-emitting substance that emits green (G) light (what is called a three-unit G\G\G tandem structure), or the light-emitting layer 771, the light-emitting layer 772, and the light-emitting layer 773 can each contain a light-emitting substance that emits blue (B) light (what is called a three-unit B\B\B tandem structure).

Note that the structures of the light-emitting substances that emit light of the same color are not limited to the above structures. For example, light-emitting units each containing a plurality of light-emitting substances may be stacked as illustrated in FIG. 16B so that a light-emitting device having a tandem structure can be obtained. FIG. 16B illustrates a structure in which a plurality of light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 16B, light-emitting substances for the light-emitting layer 771a, the light-emitting layer 771b, and the light-emitting layer 771c are selected to emit light of complementary colors, so that a structure capable of emitting white (W) light is obtained. Furthermore, light-emitting substances for the light-emitting layer 772a, the light-emitting layer 772b, and the light-emitting layer 772c are selected to emit light of complementary colors, so that a structure capable of emitting white (W) light is obtained. That is, the structure illustrated in FIG. 16C is a two-unit W\W tandem structure. Note that there is no particular limitation on the stacking order of light-emitting substances that emit light of complementary colors in the light-emitting layer 771a, the light-emitting layer 771b, and the light-emitting layer 771c. A practitioner can select the optimal stacking order as appropriate. Moreover, although not illustrated, a three-unit W\W\W tandem structure or a tandem structure with four or more units may be employed.

In the case of using the light-emitting device having a tandem structure, any of the following structures can be given, for example: a two-unit B\Y tandem structure including a light-emitting unit that emits yellow (Y) light and a light-emitting unit that emits blue (B) light; a two-unit R·G\B tandem structure including a light-emitting unit that emits red (R) and green (G) light and a light-emitting unit that emits blue (B) light; a three-unit B\Y\B tandem structure including a light-emitting unit that emits blue (B) light, a light-emitting unit that emits yellow (Y) light, and a light-emitting unit that emits blue (B) light in this order; a three-unit B\YG\B tandem structure including a light-emitting unit that emits blue (B) light, a light-emitting unit that emits yellowish-green (YG) light, and a light-emitting unit that emits blue (B) light in this order; and a three-unit B\G\B tandem structure including a light-emitting unit that emits blue (B) light, a light-emitting unit that emits green (G) light, and a light-emitting unit that emits blue (B) light in this order.

A light-emitting unit containing one light-emitting substance and a light-emitting unit containing a plurality of light-emitting substances may be used in combination as illustrated in FIG. 16C.

Specifically, in the structure illustrated in FIG. 16C, a plurality of light-emitting units (the light-emitting unit 763a, the light-emitting unit 763b, and the light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

In the structure illustrated in FIG. 16C, for example, a three-unit B\R·G·YG\B tandem structure where the light-emitting unit 763a is a light-emitting unit that emits blue (B) light, the light-emitting unit 763b is a light-emitting unit that emits red (R), green (G), and yellowish-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Note that also in FIG. 15C and FIG. 15D, each of the layer 780 and the layer 790 may independently have a stacked-layer structure of two or more layers as illustrated in FIG. 15B.

In FIG. 15E and FIG. 15F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged, and the structures of the layer 780b and the layer 790b are also interchanged.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other of the two light-emitting units when voltage is applied between the pair of electrodes.

Next, materials that can be used for the light-emitting device are described.

A conductive film transmitting visible light is used for the electrode through which light is extracted, which is either the lower electrode 761 or the upper electrode 762. A conductive film reflecting visible light is preferably used for the electrode through which light is not extracted. In the case where the display panel includes a light-emitting device emitting infrared light, it is preferable that a conductive film transmitting visible light and infrared light be used as the electrode through which light is extracted and that a conductive film reflecting visible light and infrared light be used as the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display panel.

As a material that forms the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing an appropriate combination of these metals. Other examples of the material include an indium tin oxide (also referred to as In—Sn oxide or ITO), an In—Si—Sn oxide (also referred to as ITSO), an indium zinc oxide (In—Zn oxide), and an In—W—Zn oxide. Other examples of the material include an alloy containing aluminum (an aluminum alloy) such as an alloy of aluminum, nickel, and lanthanum (Al—Ni—La), and an alloy of silver, palladium, and copper (Ag—Pd—Cu, also referred to as APC). Other examples of the material include an element that belongs to Group 1 or Group 2 of the periodic table, which is not described above (e.g., lithium, cesium, calcium, or strontium), a rare earth metal such as europium or ytterbium, an alloy containing an appropriate combination of these elements, and graphene.

The light-emitting device preferably employs a microcavity structure. Therefore, one of the pair of electrodes of the light-emitting device is preferably an electrode having properties of transmitting and reflecting visible light (a semi-transmissive and semi-reflective electrode), and the other of the pair of electrodes of the light-emitting device is preferably an electrode having a property of reflecting visible light (a reflective electrode). When the light-emitting device has a microcavity structure, light obtained from the light-emitting layer can be resonated between the electrodes, so that light emitted from the light-emitting device can be intensified.

Note that the semi-transmissive and semi-reflective electrode can have a stacked-layer structure of a conductive layer that can be used for a reflective electrode and a conductive layer that can be used for an electrode having a property of transmitting visible light (also referred to as a transparent electrode).

The transparent electrode has a light transmittance higher than or equal to 40%. For example, an electrode having a visible light (light at a wavelength greater than or equal to 400 nm and less than 750 nm) transmittance higher than or equal to 40% is preferably used as the transparent electrode of the light-emitting device. The visible light reflectance of the semi-transmissive and semi-reflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. The light-emitting device may further include, as a layer other than the light-emitting layer, a layer containing a substance having a high hole-injection property, a substance having a high hole-transport property, a hole-blocking material, a substance having a high electron-transport property, an electron-blocking material, a substance having a high electron-injection property, a substance having a bipolar property (a substance having a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may be contained. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum-dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of a substance having a high hole-transport property (a hole-transport material) and a substance having a high electron-transport property (an electron-transport material) can be used. As the hole-transport material, it is possible to use a material having a high hole-transport property that can be used for the hole-transport layer and will be described later. As the electron-transport material, it is possible to use a material having a high electron-transport property that can be used for the electron-transport layer and will be described later. A bipolar material or a TADF material may be used as one or more kinds of organic compounds.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be smoothly transferred and light emission can be efficiently obtained. With this structure, high efficiency, low-voltage driving, and a long lifetime of the light-emitting device can be achieved at the same time.

The hole-injection layer is a layer injecting holes from an anode to the hole-transport layer and a layer containing a material having a high hole-injection property. Examples of the material having a high hole-injection property include an aromatic amine compound and a composite material containing a hole-transport material and an acceptor material (an electron-accepting material).

As the hole-transport material, it is possible to use a material having a high hole-transport property that can be used for the hole-transport layer and will be described later.

As the acceptor material, an oxide of a metal that belongs to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable because it is stable in the air, has a low hygroscopic property, and is easy to handle. Alternatively, an organic acceptor material containing fluorine can be used. Alternatively, an organic acceptor material such as a quinodimethane derivative, a chloranil derivative, and a hexaazatriphenylene derivative can be used.

For example, a material that contains a hole-transport material and the above oxide of a metal belonging to Group 4 to Group 8 of the periodic table (typically, molybdenum oxide) may be used as the material having a high hole-injection property.

The hole-transport layer is a layer transporting holes, which are injected from the anode by the hole-injection layer, to the light-emitting layer. The hole-transport layer is a layer containing a hole-transport material. As the hole-transport material, a substance having a hole mobility higher than or equal to 1×10⁻⁶ cm²/Vs is preferable. Note that other substances can be also used as long as they have a property of transporting more holes than electrons. As the hole-transport material, a material having a high hole-transport property, such as a π-electron rich heteroaromatic compound (e.g., a carbazole derivative, a thiophene derivative, a furan derivative, or the like) or an aromatic amine (a compound having an aromatic amine skeleton), is preferable.

The electron-blocking layer is provided in contact with the light-emitting layer. The electron-blocking layer has a hole-transport property and contains a material capable of blocking electrons. The materials having an electron-blocking property among the above hole-transport materials can be used for the electron-blocking layer.

The electron-blocking layer has a hole-transport property, and thus can be also referred to as a hole-transport layer. Among the hole-transport layers, a layer having an electron-blocking property can be also referred to as an electron-blocking layer.

The electron-transport layer is a layer transporting electrons, which are injected from the cathode by the electron-injection layer, to the light-emitting layer. The electron-transport layer is a layer containing an electron-transport material. As the electron-transport material, a substance having an electron mobility higher than or equal to 1×10⁻⁶ cm²/Vs is preferable. Note that other substances can be also used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. The materials having a hole-blocking property among the above electron-transport materials can be used for the hole-blocking layer.

The hole-blocking layer has an electron-transport property, and thus can be also referred to as an electron-transport layer. Among the electron-transport layers, a layer having a hole-blocking property can be also referred to as a hole-blocking layer.

The electron-injection layer is a layer injecting electrons from the cathode to the electron-transport layer and a layer containing a material having a high electron-injection property. As the material having a high electron-injection property, an alkali metal, an alkaline earth metal, or a compound thereof can be used. As the material having a high electron-injection property, a composite material containing an electron-transport material and a donor material (an electron-donating material) can be also used.

The difference between the LUMO level of the material having a high electron-injection property and the work function value of the material used for the cathode is preferably small (specifically, smaller than or equal to 0.5 eV).

For the electron-injection layer, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used, for example. The electron-injection layer may have a stacked-layer structure of two or more layers. An example of the stacked-layer structure is a structure in which lithium fluoride is used for a first layer and ytterbium is provided for a second layer.

The electron-injection layer may contain an electron-transport material. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material that can be used for the hole-injection layer.

The charge-generation layer preferably includes a layer containing a material having a high electron-injection property. The layer can be also referred to as an electron-injection buffer layer. The electron-injection buffer layer is preferably provided between the charge-generation region and the electron-transport layer. By providing the electron-injection buffer layer, an injection barrier between the charge-generation region and the electron-transport layer can be lowered; thus, electrons generated in the charge-generation region can be easily injected into the electron-transport layer.

The electron-injection buffer layer preferably include an alkali metal or an alkaline earth metal, and for example, can include an alkali metal compound or an alkaline earth metal compound. Specifically, the electron-injection buffer layer preferably includes an inorganic compound containing an alkali metal and oxygen or an inorganic compound containing an alkaline earth metal and oxygen, further preferably includes an inorganic compound containing lithium and oxygen (lithium oxide (Li₂O) or the like). Alternatively, a material that can be used for the electron-injection layer can be suitably used for the electron-injection buffer layer.

The charge-generation layer preferably includes a layer containing a material having a high electron-transport property. The layer can be also referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other on the basis of cross-sectional shapes, characteristics, or the like in some cases.

Note that the charge-generation layer may contain a donor material instead of an acceptor material. For example, the charge-generation layer may include a layer containing an electron-transport material and a donor material that can be used for the electron-injection layer.

When the light-emitting units are stacked, provision of a charge-generation layer between two light-emitting units can inhibit an increase in drive voltage.

At least part of this embodiment can be implemented in combination with the other embodiments described in this specification as appropriate.

### Embodiment 6

In this embodiment, electronic devices in which the display device of one embodiment of the present invention can be used will be described.

The display device of one embodiment of the present invention can be used in a display portion of an electronic device. Thus, an electronic device with high display quality can be obtained. An electronic device with an extremely high resolution can be obtained. A highly reliable electronic device can be obtained.

Examples of electronic devices including the display device or the like of one embodiment of the present invention include display devices such as televisions and monitors, lighting devices, desktop or laptop personal computers, word processors, image reproduction devices which reproduce still images or moving images stored in recording media such as DVDs (Digital Versatile Discs), portable CD players, radios, tape recorders, headphone stereos, stereos, table clocks, wall clocks, cordless phone handsets, transceivers, car phones, cellular phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, tools such as chain saws, smoke detectors, and medical equipment such as dialyzers. Other examples include industrial equipment such as guide lights, traffic lights, conveyor belts, elevators, escalators, industrial robots, power storage systems, and power storage devices for leveling the amount of power supply and smart grid. In addition, moving objects and the like driven by fuel engines or electric motors using electric power from power storage units may also be included in the category of electronic devices. Examples of the moving objects include electric vehicles (EVs), hybrid electric vehicles (HVs) that include both an internal-combustion engine and a motor, plug-in hybrid electric vehicles (PHVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic device of one embodiment of the present invention may include a secondary battery (a battery), and it is preferable that the secondary battery be capable of being charged by contactless power transmission.

Examples of the secondary battery include a lithium ion secondary battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, and the like on the display portion. When the electronic device includes an antenna and a secondary battery, the antenna may be used for contactless power transmission.

The electronic device of one embodiment of the present invention may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic device of one embodiment of the present invention can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device including a plurality of display portions can have a function of displaying image information mainly on one display portion while displaying text information mainly on another display portion, a function of displaying a three-dimensional image by displaying images on a plurality of display portions with a parallax taken into account, or the like. Furthermore, an electronic device including an image receiving portion can have a function of taking a still image or a moving image, a function of automatically or manually correcting a taken image, a function of storing a taken image in a recording medium (an external recording medium or a recording medium incorporated in the electronic device), a function of displaying a taken image on a display portion, or the like. Note that functions of the electronic device of one embodiment of the present invention are not limited thereto, and the electronic devices can have a variety of functions.

The display device of one embodiment of the present invention can display high-resolution images. Thus, the display device of one embodiment of the present invention can be suitably used especially for a portable electronic device, a wearable electronic device (wearable device), an e-book reader, and the like. For example, the display device can be suitably used for xR devices such as a VR device and an AR device.

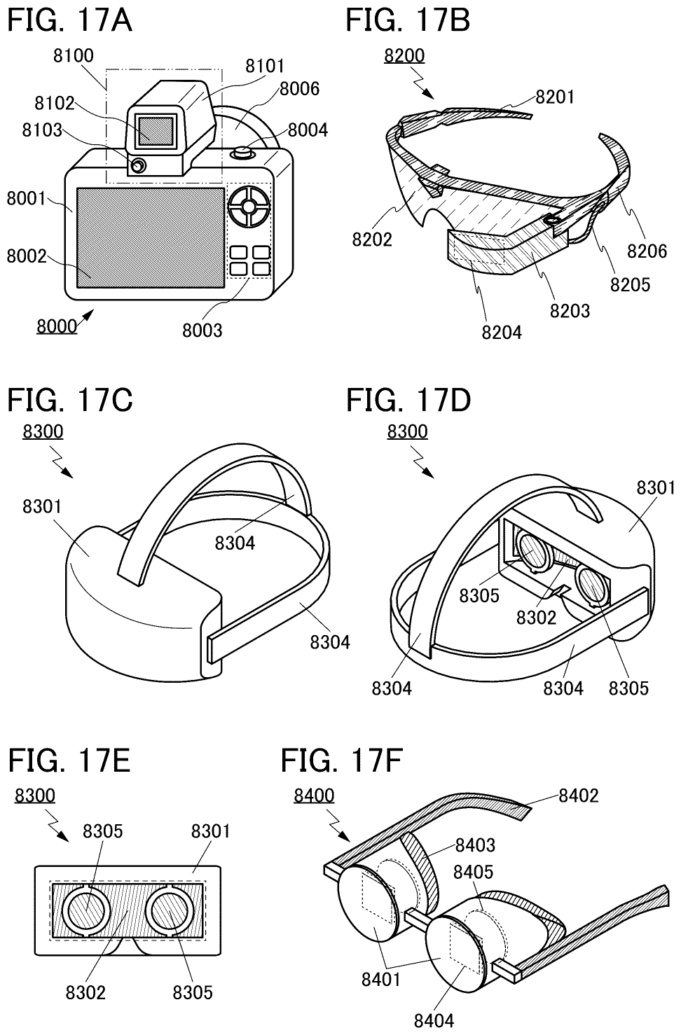

FIG. 17A is a diagram illustrating the appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing may be integrated with each other in the camera 8000.

Images can be taken with the camera 8000 at the press of the shutter button 8004 or the touch of the display portion 8002 serving as a touch panel.

The housing 8001 includes a mount including an electrode, so that the finder 8100, a stroboscope, or the like can be connected to the housing 8001.

The finder 8100 includes a housing 8101, a display portion 8102, a button 8103, and the like

The housing 8101 is attached to the camera 8000 with the mount engaging with a mount of the camera 8000. The finder 8100 can display, for example, a video received from the camera 8000 on the display portion 8102.

The button 8103 has a function of a power supply button or the like.

The display device of one embodiment of the present invention can be used in the display portion 8002 of the camera 8000 and the display portion 8102 of the finder 8100. Note that the finder 8100 may be incorporated in the camera 8000.

FIG. 17B is a diagram illustrating the appearance of a head-mounted display 8200.

The head-mounted display 8200 includes a wearing portion 8201, a lens 8202, a main body 8203, a display portion 8204, a cable 8205, and the like. A battery 8206 is incorporated in the wearing portion 8201.

The cable 8205 supplies electric power from the battery 8206 to the main body 8203. The main body 8203 includes a wireless receiver or the like to receive image data and display it on the display portion 8204. The main body 8203 includes a camera, and data on the movement of eyeballs or eyelids of a user can be used as an input means.

The wearing portion 8201 may be provided with a plurality of electrodes capable of sensing a current flowing in response to the movement of the user's eyeball in a position in contact with the user to have a function of recognizing the user's sight line. Furthermore, the wearing portion 8201 may have a function of monitoring the user's pulse with use of the current flowing through the electrodes. The wearing portion 8201 may include sensors such as a temperature sensor, a pressure sensor, and an acceleration sensor so that the user's biological information can be displayed on the display portion 8204 and an image displayed on the display portion 8204 can be changed in accordance with the movement of the user's head.

The display device of one embodiment of the present invention can be used in the display portion 8204.

FIG. 17C to FIG. 17E are diagrams illustrating the appearance of a head-mounted display 8300. The head-mounted display 8300 includes a housing 8301, a display portion 8302, a band-like fixing member 8304, and a pair of lenses 8305.

A user can perceive display on the display portion 8302 through the lenses 8305. Note that the display portion 8302 is preferably placed in the curved state, in which case the user can feel a high realistic sensation. Another image displayed in another region of the display portion 8302 is viewed through the lenses 8305, so that three-dimensional display using parallax or the like can be performed. Note that the structure is not limited to the structure in which one display portion 8302 is provided; two display portions 8302 may be provided and one display portion may be provided per eye of the user.

The display device of one embodiment of the present invention can be used for the display portion 8302. The display device of one embodiment of the present invention can achieve an extremely high resolution. For example, a pixel is not easily seen by the user even when the user sees display that is magnified with use of the lenses 8305 as illustrated in FIG. 17E. In other words, a video with a strong sense of reality can be seen by the user with use of the display portion 8302.

FIG. 17F is a diagram illustrating the appearance of a goggles-type head-mounted display 8400. The head-mounted display 8400 includes a pair of housings 8401, a wearing portion 8402, and a cushion 8403. A display portion 8404 and a lens 8405 are provided in each of the pair of housings 8401. The pair of display portions 8404 may display different images, whereby three-dimensional display using parallax can be performed.

A user can see display on the display portion 8404 through the lens 8405. The lens 8405 has a focus adjustment mechanism and can adjust the position according to the user's eyesight. The display portion 8404 is preferably a square or a horizontal rectangle. This can improve a realistic sensation.

The wearing portion 8402 preferably has plasticity and elasticity so as to be adjusted to fit the size of the user's face and not to slide down. In addition, part of the wearing portion 8402 preferably has a vibration mechanism functioning as a bone conduction earphone. Thus, without additionally requiring an audio device such as earphones or a speaker, the user can enjoy video and sound only by wearing the head-mounted display 8400. Note that the housing 8401 may have a function of outputting sound data by wireless communication.

The wearing portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. When a sponge or the like whose surface is covered with cloth, leather (natural leather or synthetic leather), or the like is used, a gap is unlikely to be generated between the user's face and the cushion 8403, whereby light leakage can be suitably prevented. Using such a material is preferable because it has a soft texture and the user does not feel cold when wearing the head-mounted display 8400 in a cold season, for example. The member to be in contact with the user's skin, such as the cushion 8403 or the wearing portion 8402, is preferably detachable, in which case cleaning or replacement can be easily performed.

At least part of this embodiment can be implemented in combination with the other embodiments described in this specification as appropriate.

### REFERENCE NUMERALS

PIX: pixel circuit, RES: resistor, SW: switch, 10: display device, 20: layer, 21a: circuit, 21b: circuit, 21: source driver, 22: gate driver, 23: functional circuit, 25: region, 30a: layer, 30b: layer, 30: layer, 31: dividing pixel array, 34: latch circuit, 35: pass transistor logic circuit, 51: receiver circuit, 52: serial-to-parallel converter circuit, 53: shift register circuit, 54: latch circuit, 55: level shift circuit, 56: voltage generation circuit, 57: band gap reference circuit, 58: bias generation circuit, 59: buffer amplifier circuit, 100: transistor, 102: substrate, 104e: conductive layer, 104: conductive layer, 106: insulating layer, 108: semiconductor layer, 110a: insulating layer, 110b: insulating layer, 110c: insulating layer, 110: insulating layer, 112a: conductive layer, 112a_1: conductive layer, 112a_2: conductive layer, 112b: conductive layer, 141: opening, 150: insulating layer, 151: opening, 200A: display panel, 200a: display panel, 200b: display panel, 200: display panel, 201: layer, 210a: light-emitting element, 210B: light-emitting element, 210b: light-emitting element, 210c: light-emitting element, 210G: light-emitting element, 210R: light-emitting element, 210: light-emitting element, 211B: pixel electrode, 211C: connection electrode, 211G: pixel electrode, 211R: pixel electrode, 211: pixel electrode, 212b: conductive layer, 212B: organic layer, 212G: organic layer, 212R: organic layer, 212W: organic layer, 212: organic layer, 213: common electrode, 214: common layer, 215B: conductive layer, 215G: conductive layer, 215R: conductive layer, 216B: coloring layer, 216G: coloring layer, 216R: coloring layer, 221: protective layer, 222: insulating layer, 223: insulating layer, 224a: pixel, 224b: pixel, 225: insulating layer, 226: resin layer, 228: layer, 230: connection portion, 240: capacitor, 241: conductive layer, 243: insulating layer, 245: conductive layer, 250: pixel, 251: conductive layer, 252: conductive layer, 253: conductive layer, 254: insulating layer, 255a: insulating layer, 255b: insulating layer, 255c: insulating layer, 256: plug, 257: through electrode, 258: conductive layer, 259: conductive layer, 261: insulating layer, 262: insulating layer, 264: insulating layer, 265: insulating layer, 266: insulating layer, 267: insulating layer, 268: insulating layer, 270: substrate, 271: plug, 272: plug, 273: plug, 274: plug, 275: plug, 276: adhesive layer, 280: display module, 281: display portion, 282: circuit portion, 283: circuit portion, 284a: pixel, 284: circuit portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 320A: transistor, 320B: transistor, 321: semiconductor layer, 323: insulating layer, 324: conductive layer, 325: conductive layer, 326: insulating layer, 327: conductive layer, 328: insulating layer, 329: insulating layer, 332: insulating layer, 333: insulating layer, 334: insulating layer, 335: insulating layer, 336: insulating layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: wearing portion, 8202: lens, 8203: main body, 8204: display portion, 8205: cable, 8206: battery, 8300: head-mounted display, 8301: housing, 8302: display portion, 8304: fixing member, 8305: lens, 8400: head-mounted display, 8401: housing, 8402: wearing portion, 8403: cushion, 8404: display portion, 8405: lens

1. A display device comprising:
a pixel circuit and a driver circuit comprising a region overlapping with the pixel circuit,
wherein the driver circuit comprises a first circuit and a second circuit,
wherein the second circuit comprises a region overlapping with the first circuit,
wherein the pixel circuit comprises a region overlapping with the second circuit,
wherein the first circuit comprises a first transistor comprising silicon in a channel formation region,
wherein the second circuit comprises a second transistor comprising a metal oxide in a semiconductor layer,
wherein the pixel circuit comprises a third transistor comprising a metal oxide in a semiconductor layer, and
wherein, in a cross-sectional view, the second transistor comprises a channel formation region provided along a side surface of a first insulating layer.

2. The display device according to claim 1, comprising a first layer, a second layer, and a third layer,
wherein the second layer is provided between the first layer and the third layer,
wherein the pixel circuit is provided in the third layer,
wherein the first circuit is provided in the first layer, and
wherein the second circuit is provided in the second layer.

3. A display device comprising:
a first layer, a second layer, and a third layer,
wherein the second layer is provided between the first layer and the third layer,
wherein a pixel circuit is provided in the third layer,
wherein a driver circuit of the pixel circuit comprises a first circuit provided in the first layer and a second circuit provided in the second layer,
wherein the first circuit comprises a first transistor comprising silicon in a channel formation region,
wherein the second circuit comprises a second transistor comprising a metal oxide in a semiconductor layer,
wherein the pixel circuit comprises a third transistor comprising a metal oxide in a semiconductor layer, and
wherein, in a cross-sectional view, the second transistor comprises a channel formation region provided along a side surface of a first insulating layer included in the second layer.

4. A display device comprising:
a first layer, a second layer, and a third layer,
wherein the second layer is provided between the first layer and the third layer,
wherein a pixel circuit comprises a first part provided in the second layer and a second part provided in the third layer,
wherein a driver circuit of the pixel circuit comprises a first circuit provided in the first layer and a second circuit provided in the second layer,
wherein the first circuit comprises a first transistor comprising silicon in a channel formation region,
wherein the second circuit comprises a second transistor comprising a metal oxide in a semiconductor layer,
wherein the first part of the pixel circuit comprises a fourth transistor comprising a metal oxide in a semiconductor layer,
wherein the second part of the pixel circuit comprises a third transistor comprising a metal oxide in a semiconductor layer, and
wherein, in a cross-sectional view, the second transistor and the fourth transistor each comprise a channel formation region provided along a side surface of a first insulating layer included in the second layer.

5. The display device according to claim 4,
wherein the third transistor is configured to be a driving transistor in the pixel circuit,
wherein the fourth transistor is configured to be a selection transistor in the pixel circuit,
wherein the third transistor comprises a first conductive layer configured to be a first gate electrode and a second conductive layer configured to be a second gate,
wherein the first conductive layer and the second conductive layer are electrically connected to each other, and
wherein the second conductive layer is electrically connected to one of a source electrode and a drain electrode of the fourth transistor.

6. The display device according to claim 1,
wherein, in a cross-sectional view of the second transistor, a third conductive layer, the first insulating layer, and a fourth conductive layer are stacked in this order, and an opening is provided in the first insulating layer and the fourth conductive layer so as to reach the third conductive layer.

7. The display device according to claim 6,
wherein the second transistor comprises:
the semiconductor layer comprising the metal oxide so as to cover the opening;
a second insulating layer provided over the fourth conductive layer and the semiconductor layer comprising the metal oxide so as to cover a depressed portion caused by the opening; and
a fifth conductive layer provided over the second insulating layer so as to fill the depressed portion caused by the opening.

8. The display device according to claim 1,
wherein the first circuit and the second circuit are components of a source driver, and
wherein the second circuit comprises a pass transistor logic circuit.

9. The display device according to claim 1,
wherein the second circuit comprises a latch circuit.

10. The display device according to claim 1,
wherein, in a top view, the driver circuit is provided in a rectangular region, and
wherein the driver circuit is configured to drive a plurality of the pixel circuits provided over the rectangular region.

11. The display device according to claim 10,
wherein a plurality of the rectangular regions are arranged in a matrix.

12. The display device according to claim 1,
wherein the pixel circuit comprises an organic EL element.

13. An electronic device comprising the display device according to claim 1, a lens, and a visibility adjustment mechanism.

14. The display device according to claim 3,
wherein, in the second layer, a third conductive layer, the first insulating layer, and a fourth conductive layer are stacked in this order, and an opening is provided in the first insulating layer and the fourth conductive layer so as to reach the third conductive layer.

15. The display device according to claim 14,
wherein the second transistor comprises:
the semiconductor layer comprising the metal oxide so as to cover the opening;
a second insulating layer provided over the fourth conductive layer and the semiconductor layer comprising the metal oxide so as to cover a depressed portion caused by the opening; and
a fifth conductive layer provided over the second insulating layer so as to fill the depressed portion caused by the opening.

16. The display device according to claim 3,
wherein the first circuit and the second circuit are components of a source driver, and
wherein the second circuit comprises a pass transistor logic circuit.

17. The display device according to claim 3,
wherein the second circuit comprises a latch circuit.

18. The display device according to claim 3,
wherein, in a top view, the driver circuit is provided in a rectangular region, and
wherein the driver circuit is configured to drive a plurality of the pixel circuits provided over the rectangular region.

19. The display device according to claim 18,
wherein a plurality of the rectangular regions are arranged in a matrix.

20. The display device according to claim 3,
wherein the pixel circuit comprises an organic EL element.

21. An electronic device comprising the display device according to claim 3, a lens, and a visibility adjustment mechanism.

22. The display device according to claim 4,
wherein, in the second layer, a third conductive layer, the first insulating layer, and a fourth conductive layer are stacked in this order, and an opening is provided in the first insulating layer and the fourth conductive layer so as to reach the third conductive layer.

23. The display device according to claim 22,
wherein the second transistor comprises:
the semiconductor layer comprising the metal oxide so as to cover the opening;
a second insulating layer provided over the fourth conductive layer and the semiconductor layer comprising the metal oxide so as to cover a depressed portion caused by the opening; and
a fifth conductive layer provided over the second insulating layer so as to fill the depressed portion caused by the opening.

24. The display device according to claim 4,
wherein the first circuit and the second circuit are components of a source driver, and
wherein the second circuit comprises a pass transistor logic circuit.

25. The display device according to claim 4,
wherein the second circuit comprises a latch circuit.

26. The display device according to claim 4,
wherein, in a top view, the driver circuit is provided in a rectangular region, and
wherein the driver circuit is configured to drive a plurality of the pixel circuits provided over the rectangular region.

27. The display device according to claim 26,
wherein a plurality of the rectangular regions are arranged in a matrix.

28. The display device according to claim 4,
wherein the pixel circuit comprises an organic EL element.

29. An electronic device comprising the display device according to claim 4, a lens, and a visibility adjustment mechanism.
